(19) United States
(12) Patent Application Publication
(10) Pub. No.: US 2026/0059851 A1
(43) Pub. Date: Feb. 26, 2026

(54) SEMICONDUCTOR DEVICES AND METHODS FOR FABRICATING THE SAME

(71) Applicant: Samsung Electronics Co., Ltd., Suwon-si (KR)

(72) Inventors: DONG HOON HWANG, Suwon-si (KR); SEONG KWANG KIM, Suwon-si (KR); BYUNG HO MOON, Suwon-si (KR)

(21) Appl. No.: 19/094,256

(22) Filed: Mar. 28, 2025

(30) Foreign Application Priority Data
Aug. 22, 2024 (KR) 10-2024-0112902

(51) Int. Cl. H10D 84/83; H01L 23/522; H01L 23/528; H10D 30/00; H10D 30/01; H10D 30/43; H10D 62/10; H10D 64/23; H10D 84/01

(52) U.S. Cl. CPC H10D 84/832; H01L 23/5222; H01L 23/5226; H01L 23/5228; H01L 23/5283; H10D 30/43; H10D 30/502; H10D 62/121; H10D 64/256; H10D 84/8312; H10D 30/014; H10D 30/0191; H10D 84/0149

(57) ABSTRACT

A semiconductor device includes a first lower epitaxial pattern on a side of a gate structure, wherein the first lower epitaxial pattern is connected to a lower active pattern; a first upper epitaxial pattern on another side of the gate structure, wherein the first upper epitaxial pattern is connected to an upper active pattern; a cut pattern that is spaced apart from the lower and upper active patterns, is adjacent the gate structure, and extends in a first direction; and a via structure connected to the first lower epitaxial pattern and the first upper epitaxial pattern in the cut pattern, wherein the via structure includes a first pillar part overlapping the first upper epitaxial pattern in a second direction, a second pillar part overlapping the first lower epitaxial pattern in the second direction, and a connecting part extending in the first direction to connect the first and second pillar parts.

### CROSS-REFERENCE TO RELATED APPLICATIONS

This application claims priority from Korean Patent Application No. 10-2024-0112902, filed on Aug. 22, 2024 in the Korean Intellectual Property Office and all the benefits accruing therefrom under 35 U.S.C. 119, the contents of which in its entirety are herein incorporated by reference.

### BACKGROUND OF THE INVENTION

The present inventive concept relates to electronic devices, such as semiconductor devices and methods for fabricating the same. More specifically, the present inventive concept may relate to semiconductor devices including a stacked multi-gate transistor and methods for fabricating the same.

As one of scaling technologies for increasing density of an integrated circuit device, a multi-gate transistor in which a silicon body having a fin shape or a nanowire shape is formed on a substrate and a gate is formed on a surface of the silicon body has been proposed.

Since such a multi-gate transistor utilizes a three-dimensional channel, scaling may be relatively easy to perform. Further, even if a gate length of the multi-gate transistor is not increased, the current control capability may be improved. Furthermore, a SCE (short channel effect) in which potential of a channel region is influenced by a drain voltage may be effectively suppressed.

In addition, in order to implement more elements in the same area, a semiconductor device using a stacked multi-gate transistor in which the multi-gate transistor of an upper region is stacked on the multi-gate transistor of a lower region is being researched.

### SUMMARY OF THE INVENTION

Aspects of the present inventive concept may provide semiconductor devices having improved performance and degree of integration.

Aspects of the present inventive concept may provide methods for fabricating semiconductor devices having improved performance and degree of integration.

However, aspects of the present inventive concept are not restricted to the one set forth herein. The above and other aspects of the present inventive concept will become more apparent to one of ordinary skill in the art to which the present inventive concept pertains by referencing the detailed description of the present inventive concept given below.

According to an aspect of the present inventive concept, there is provided a semiconductor device comprising a substrate; an upper active pattern that extends in a first direction on the substrate; a lower active pattern between the upper active pattern and an upper face of the substrate in a second direction that intersects the first direction and the upper face of the substrate, wherein the lower active pattern extends in the first direction; a gate structure that extends in a third direction that intersects the first direction and the second direction, on the lower active pattern and the upper active pattern; a first lower epitaxial pattern on a first side of the gate structure, wherein the first lower epitaxial pattern is connected to the lower active pattern; a first upper epitaxial pattern on a second side of the gate structure, wherein the first upper epitaxial pattern is connected to the upper active pattern; a cut pattern that is spaced apart from the lower active pattern and the upper active pattern in the third direction, is adjacent the gate structure, and extends in the first direction; and a via structure that is connected to the first lower epitaxial pattern and the first upper epitaxial pattern, in the cut pattern, wherein the via structure includes a first pillar part that overlaps the first upper epitaxial pattern in the third direction, a second pillar part that overlaps the first lower epitaxial pattern in the third direction, and a connecting part that extends in the first direction and connects the first pillar part and the second pillar part.

According to an aspect of the present inventive concept, there is provided a semiconductor device comprising a substrate; an upper active pattern that extends in a first direction on the substrate; a lower active pattern between the upper active pattern and an upper face of the substrate in a second direction that intersects the first direction and the upper face of the substrate, wherein the lower active pattern extends in the first direction; a gate structure that extends in a third direction that intersects the first direction and the second direction, on the lower active pattern and the upper active pattern; a first lower epitaxial pattern on a first side of the gate structure, wherein the first lower epitaxial pattern is connected to the lower active pattern; a second lower epitaxial pattern on a second side of the gate structure, wherein the second lower epitaxial pattern is connected to the lower active pattern; a first upper epitaxial pattern on the first side of the gate structure, wherein the first upper epitaxial pattern is connected to the upper active pattern; a second upper epitaxial pattern on the second side of the gate structure, wherein the second upper epitaxial pattern is connected to the upper active pattern; a cut pattern that is spaced apart from the lower active pattern and the upper active pattern in the third direction, is adjacent the gate structure, and extends in the first direction; and a via structure that is connected to the second lower epitaxial pattern and the first upper epitaxial pattern, in the cut pattern, wherein the via structure includes a first via recess that extends from an upper face of the via structure and overlaps the second upper epitaxial pattern in the third direction, and a second via recess that extends from a lower face of the via structure and overlaps the first lower epitaxial pattern in the third direction.

According to an aspect of the present inventive concept, there is provided a semiconductor device comprising a substrate that includes a first face and a second face that is opposite to the first face in a first direction; a lower active pattern and an upper active pattern that are sequentially stacked in the first direction, and each extend in a second direction that intersects the first direction; an intermediate insulating pattern between the lower active pattern and the upper active pattern; a gate structure that extends in a third direction that intersects the first direction and the second direction, wherein each of the lower active pattern and the upper active pattern penetrates through the gate structure; a first lower epitaxial pattern on a first side of the gate structure, wherein the first lower epitaxial pattern is connected to the lower active pattern; a second lower epitaxial pattern on a second side of the gate structure, wherein the second lower epitaxial pattern is connected to the lower active pattern; a first upper epitaxial pattern on the first side of the gate structure, wherein the first upper epitaxial pattern is connected to the upper active pattern; a second upper epitaxial pattern on the second side of the gate structure, wherein the second upper epitaxial pattern is connected to the upper active pattern; a cut pattern that is spaced apart from the lower active pattern and the upper active pattern in the third direction, is adjacent the gate structure, and extends in the second direction; a via structure in the cut pattern, wherein the via structure includes a connecting part that overlaps the intermediate insulating pattern and the gate structure in the third direction, a first pillar part that overlaps the first upper epitaxial pattern and is free of overlap with the second upper epitaxial pattern in the third direction, and a second pillar part that overlaps the second lower epitaxial pattern and is free of overlap with the first lower epitaxial pattern in the third direction; a first connecting pattern that extends in the third direction on an upper face of the first upper epitaxial pattern, and connects the first upper epitaxial pattern and the first pillar part; and a second connecting pattern that extends in the third direction on a lower face of the second lower epitaxial pattern, and connects the second lower epitaxial pattern and the second pillar part.

### BRIEF DESCRIPTION OF THE DRAWINGS

The above and other aspects and features of the present inventive concept will become more apparent by describing in detail embodiments thereof with reference to the attached drawings, in which:

FIG. 1 is a layout diagram for explaining a semiconductor device according to some embodiments.

FIG. 2 is a schematic cross-sectional view taken along A-A′ of FIG. 1.

FIG. 3 is a schematic cross-sectional view taken along B-B′ of FIG. 1.

FIG. 4 is a schematic cross-sectional view taken along C-C′ of FIG. 1.

FIG. 5 is a schematic cross-sectional view taken along D-D′ of FIG. 1.

FIG. 6 is a schematic cross-sectional view taken along E-E′ of FIG. 1.

FIG. 7 is a schematic cross-sectional view for explaining a semiconductor device according to some embodiments.

FIGS. 8 to 11 are various schematic cross-sectional views for explaining a semiconductor device according to some embodiments.

FIG. 12 is a layout diagram for explaining a semiconductor device according to some embodiments.

FIGS. 13 to 45 are intermediate stage diagrams for explaining the method for fabricating the semiconductor device according to some embodiments.

### DETAILED DESCRIPTION OF THE INVENTION

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present inventive concept.

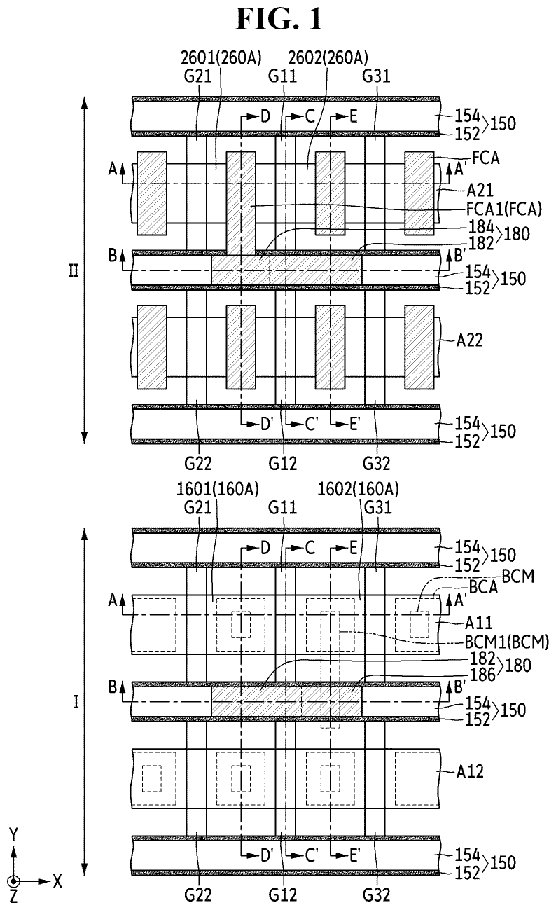

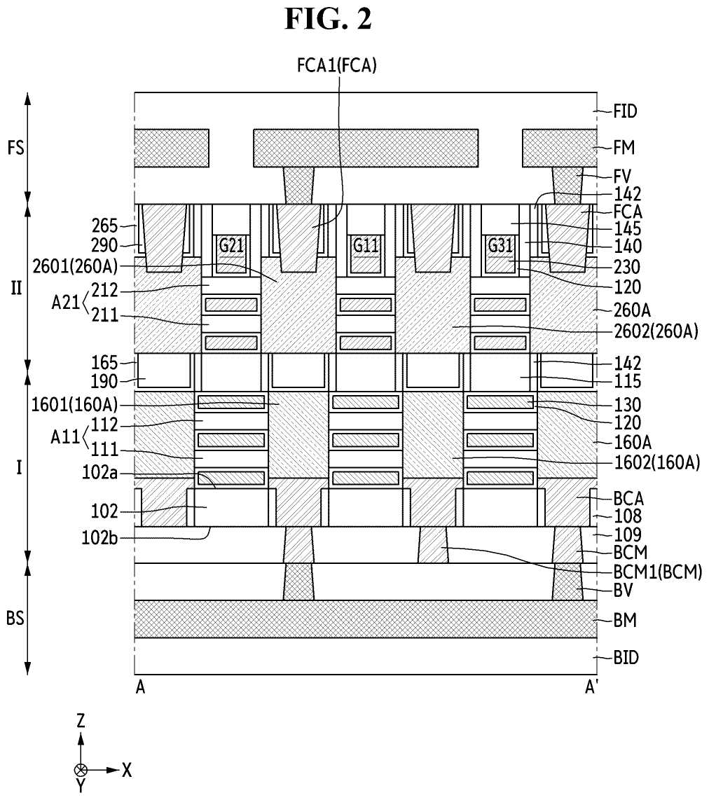

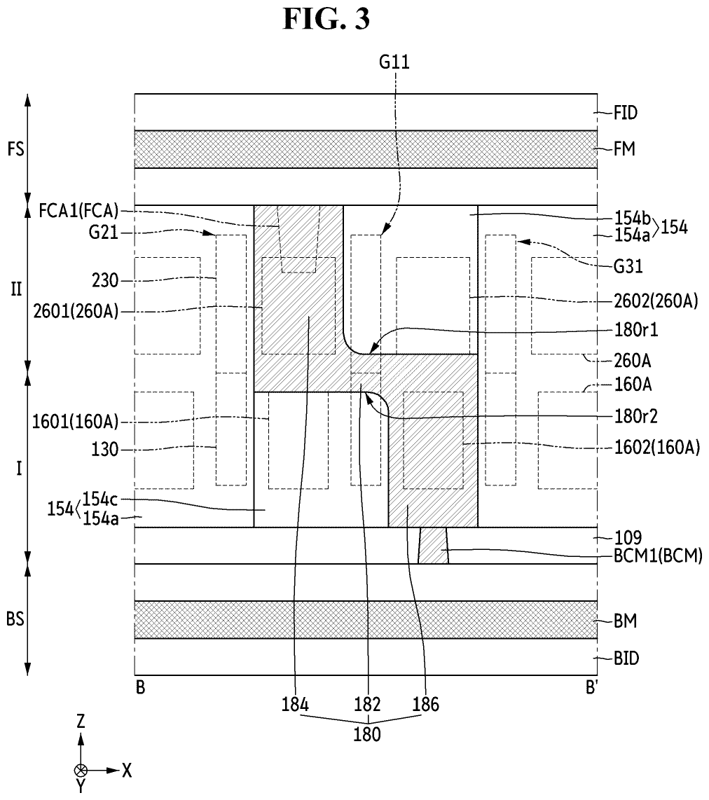

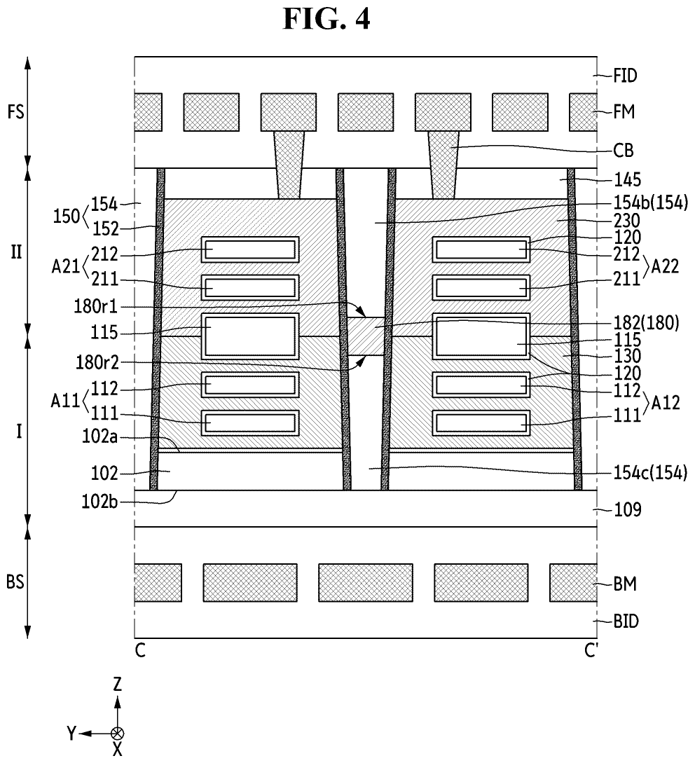

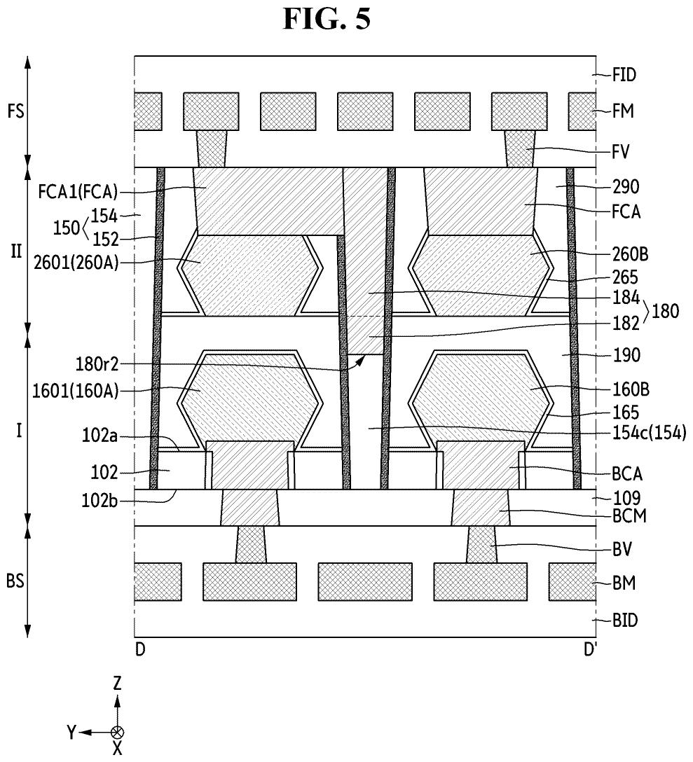

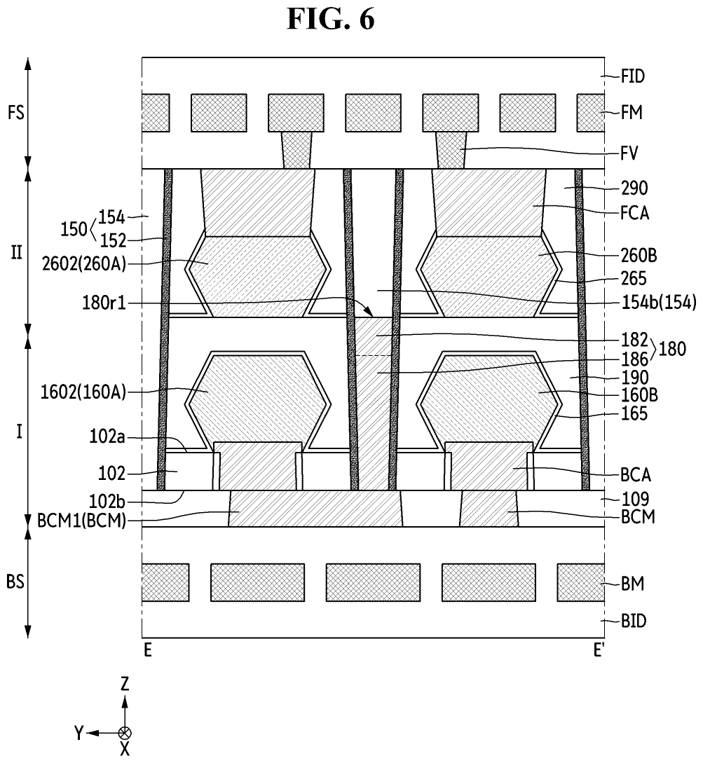

FIG. 1 is a layout diagram for explaining a semiconductor device according to some embodiments. FIG. 2 is a schematic cross-sectional view taken along A-A′ of FIG. 1. FIG. 3 is a schematic cross-sectional view taken along B-B′ of FIG. 1. FIG. 4 is a schematic cross-sectional view taken along C-C′ of FIG. 1. FIG. 5 is a schematic cross-sectional view taken along D-D′ of FIG. 1. FIG. 6 is a schematic cross-sectional view taken along E-E′ of FIG. 1.

Referring to FIGS. 1 to 6, a semiconductor device according to some embodiments may include a first region I and a second region II.

The first region I and the second region II may be (sequentially) stacked along a first direction Z. In the first region I and the second region II, transistors of the same conductivity type may be formed, or transistors of different conductivity types may be formed. In the following explanation, the explanation will be mainly given assuming that the first region I is a PFET (p-type field effective transistor) region, and the second region II is an NFET (n-type field effective transistor) region. However, this is merely an example, and a person having ordinary skill in the art to which the present inventive concept pertains will understand that the first region I may be the NFET region and the second region II may be the PFET region, or both the first region I and the second region II may be the NFET region, or both the first region I and the second region II may be the PFET region.

The semiconductor device according to some embodiments may include a substrate 102, lower active patterns A11 and A12, upper active patterns A21 and A22, intermediate insulating pattern 115, gate structures G11, G12, G21, G22, G31 and G32, a cut pattern 150, a lower source/drain patterns 160A and 160B, a first etch stop layer 165, a first interlayer insulating film 190, upper source/drain patterns 260A and 260B, a second etch stop layer 265, a second interlayer insulating film 290, front source/drain contacts FCA, a front wiring structure FS, a back source/drain contacts BCA, back connecting contacts BCM, a back wiring structure BS, and a via structure 180.

The substrate 102 may be bulk silicon or silicon-on-insulator (SOI). In some embodiments, the substrate 102 may be a silicon substrate or may include other materials, for example, silicon germanium, silicon germanium on insulator (SGOI), indium antimonide, lead telluride, indium arsenide, indium phosphide, gallium arsenide and/or gallium antimonide. In some embodiments, the substrate 102 may be an epitaxial layer formed on a base substrate. As used herein, the term “and/or” includes any and all combinations of one or more of the associated listed items.

In some embodiments, the substrate 102 may be an insulating substrate including an insulating material. For example, the substrate 102 may include, but not limited to, silicon oxide, silicon oxynitride, silicon oxycarbonitride and/or a combination thereof. As an example, the substrate 102 may include a silicon oxide film.

The substrate 102 may include a first face 102a and a second face 102b that are opposite to each other (in the first direction Z). In this specification, the first face 102a is also referred to as a front side (e.g., an upper side) of the substrate 102, and the second face 102b is also referred to as a back side (e.g., a lower side) of the substrate 102.

The lower active patterns A11 and A12 may be disposed in the first region I. The lower active patterns A11 and A12 may be spaced apart from the substrate 102 in the first direction Z. The lower active patterns A11 and A12 may be spaced apart from each other (in a third direction Y that intersects the first direction Z), and extend side by side in a second direction X that intersects the first direction Z. For example, the lower active patterns A11 and A12 may include a first lower active pattern A11 and a second lower active pattern A12 that each extend in the second direction X. The first lower active pattern A11 and the second lower active pattern A12 may be spaced apart from each other in a third direction Y that intersects the first direction Z and the second direction X. The first direction Z may be perpendicular to the first face 102a and/or the second face 102b. The second direction X and the third direction Y may be parallel with the first face 102a and/or the second face 102b. The second direction X and the third direction Y may intersect each other.

In some embodiments, each of the lower active patterns A11 and A12 may include a plurality of lower bridge patterns 111 and 112 that are stacked in sequence in the first direction Z and spaced apart from each other (in the first direction Z). The lower bridge patterns 111 and 112 may be used as a channel region of an MBCFET including a multi-bridge channel in the first region I. The number of bridge patterns included in each of the lower active patterns A11 and A12 in the drawings is an example embodiment and is not limited to that shown in the drawings.

The upper active patterns A21 and A22 may be disposed in the second region II. The upper active patterns A21 and A22 may be spaced apart from the lower active patterns A11 and A12 in the first direction Z. The upper active patterns A21 and A22 may be spaced apart from each other (in the third direction Y), and may extend side by side in the second direction X. For example, each of the upper active patterns A21 and A22 may include a first upper active pattern A21 and a second upper active pattern A22 that extend long in the second direction X. The first upper active pattern A21 may be spaced apart from the first lower active pattern A11 in the first direction Z. The second upper active pattern A22 may be spaced apart from the second lower active pattern A12 in the first direction Z. The first upper active pattern A21 may overlap the first lower active pattern A11 in the first direction Z, and the second upper active pattern A22 may overlap the second lower active pattern A12 in the first direction Z.

In some embodiments, each of the upper active patterns A21 and A22 may include a plurality of upper bridge patterns 211 and 212 that are stacked in sequence in the first direction Z and spaced apart from each other (in the first direction Z). The upper bridge patterns 211 and 212 may be used as a channel region of an MBCFET® including a multi-bridge channel in the second region II. The number of bridge patterns included in each of the upper active patterns A21 and A22 in the drawings is an example embodiment and is not limited to that shown in the drawings.

Each of the lower active patterns A11 and A12 and the upper active patterns A21 and A22 may include silicon (Si) and/or germanium (Ge), which are elemental semiconductor materials. In some embodiments, each of the lower active patterns A11 and A12 and the upper active patterns A21 and A22 may include a compound semiconductor, for example, a group IV-IV compound semiconductor and/or a group III-V compound semiconductor. The group IV-IV compound semiconductor may be, for example, a binary compound or a ternary compound including at least two of carbon (C), silicon (Si), germanium (Ge), and tin (Sn), or a compound formed by doping these elements with a group IV element. The group III-V compound semiconductor may be, for example, one of a binary compound, a ternary compound or a quaternary compound formed by combining aluminum (Al), gallium (Ga), and/or indium (In), which are group III elements, with phosphorus (P), arsenic (As), and/or antimony (Sb) which are group V elements.

The intermediate insulating pattern 115 may be interposed between the lower active patterns A11 and A12 and the upper active patterns A21 and A22 in the first direction Z. For example, the intermediate insulating pattern 115 may be interposed between the first lower active pattern A11 and the first upper active pattern A21, and may be interposed between the second lower active pattern A12 and the second upper active pattern A22. In some embodiments, the intermediate insulating pattern 115 may extend long in the second direction X.

The intermediate insulating pattern 115 may include, but not limited to, silicon oxide, silicon oxynitride, silicon oxycarbonitride, and/or a combination thereof. As an example, the intermediate insulating pattern 115 may include a silicon nitride film.

The gate structures G11, G12, G21, G22, G31 and G32 may be formed on the lower active patterns A11 and A12 and the upper active patterns A21 and A22. The gate structures G11, G12, G21, G22, G31 and G32 may intersect (e.g., overlap in the first direction Z) the lower active patterns A11 and A12 and the upper active patterns A21 and A22. For example, the gate structures G11, G12, G21, G22, G31 and G32 may include a first gate structure G11, a second gate structure G12, a third gate structure G21, a fourth gate structure G22, a fifth gate structure G31, and a sixth gate structure G32 which each extend in the third direction Y.

The first gate structure G11 may intersect (e.g., overlap in the first direction Z) the first lower active pattern A11 and the first upper active pattern A21. The first gate structure G11 may be interposed between the third gate structure G21 and the fifth gate structure G31 in the second direction X. The second gate structure G12 may intersect the second lower active pattern A12 and the second upper active pattern A22. The second gate structure G12 may be arranged along the third direction Y together with the first gate structure G11. For example, the second gate structure G12 may overlap the first gate structure G11 in the third direction Y. The second gate structure G12 may be interposed between the fourth gate structure G22 and the sixth gate structure G32 in the second direction X.

The third gate structure G21 may intersect (e.g., overlap in the first direction Z) the first lower active pattern A11 and the first upper active pattern A21. The third gate structure G21 may be spaced apart from the first gate structure G11 in the second direction X. The fourth gate structure G22 may intersect (e.g., overlap in the first direction Z) the second lower active pattern A12 and the second upper active pattern A22. The fourth gate structure G22 may be disposed along the third direction Y together with the third gate structure G21. For example, the fourth gate structure G22 may overlap the third gate structure G21 in the third direction Y.

The fifth gate structure G31 may intersect (e.g., overlap in the first direction Z) the first lower active pattern A11 and the first upper active pattern A21. The fifth gate structure G31 may be spaced apart from the first gate structure G11 in the second direction X. The sixth gate structure G32 may intersect (e.g., overlap in the first direction Z) the second lower active pattern A12 and the second upper active pattern A22. The sixth gate structure G32 may be arranged along the third direction Y together with the fifth gate structure G31. For example, the sixth gate structure G32 may overlap the fifth gate structure G31 in the third direction Y.

In some embodiments, each of the gate structures G11, G12, G21, G22, G31 and G32 may include a gate dielectric film 120, a first gate electrode 130, a second gate electrode 230, a gate spacer 140, and a gate capping film 145.

The gate dielectric film 120 may be interposed between the lower active patterns A11 and A12 and the first gate electrode 130, and between the upper active patterns A21 and A22 and the second gate electrode 230. The gate dielectric film 120 may include a dielectric material, for example, silicon oxide, silicon oxynitride, silicon nitride, a high-dielectric constant material having a higher dielectric constant than silicon oxide, and/or a combination thereof. The high-dielectric constant material may include, for example, but not limited to, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate and/or a combination thereof.

Although the gate dielectric film 120 is only shown as being a single film, this is merely an example, and it goes without saying that the gate dielectric film 120 may be a multi-layer film formed by stacking a plurality of dielectric films. For example, the gate dielectric film 120 may include an interfacial film and a high dielectric film that are sequentially stacked on the lower active patterns A11 and A12 and the upper active patterns A21 and A22. The interfacial film may include, for example, an oxide film formed by oxidizing the surfaces of the lower active patterns A11 and A12 and the surfaces of the upper active patterns A21 and A22. The high dielectric constant film may include, for example, a high-dielectric constant material having a higher dielectric constant than silicon oxide.

In some embodiments, a part of the gate dielectric film 120 may be interposed between the substrate 102 and the first gate electrode 130. For example, the gate dielectric film 120 may further extend along (on) the first face 102a of the substrate 102. In some embodiments, a part of the gate dielectric film 120 may be interposed between the intermediate insulating pattern 115 and the first gate electrode 130 and/or between the intermediate insulating pattern 115 and the second gate electrode 230. For example, the gate dielectric film 120 may further extend along the periphery of the intermediate insulating pattern 115.

The first gate electrode 130 may be disposed in the first region I. The first gate electrode 130 may intersect (e.g., overlap in the first direction Z) the lower active patterns A11 and A12. For example, each of the lower bridge patterns 111 and 112 may extend in the second direction X and penetrate (extend in) the first gate electrode 130. The first gate electrode 130 may extend around (e.g., surround) (the periphery of) each of the lower bridge patterns 111 and 112.

The second gate electrode 230 may be disposed in the second region II. The second gate electrode 230 may intersect (e.g., overlap in the first direction Z) the upper active patterns A21 and A22. For example, each of the upper bridge patterns 211 and 212 may extend in the second direction X and penetrate (extend in) the second gate electrode 230. The second gate electrode 230 may extend around (e.g., surround) (the periphery of) each of the upper bridge patterns 211 and 212.

Each of the first gate electrode 130 and the second gate electrode 230 may include a conductive material, for example, but not limited to, TiN, WN, TaN, Ru, TiC, TaC, Ti, Ag, Al, TiAl, TiAlN, TiAlC, TaCN, TaSiN, Mn, Zr, W, Al and/or a combination thereof. Each of the first gate electrode 130 and the second gate electrode 230 may be formed, but not limited to, by a replacement process.

Although each of the first gate electrode 130 and the second gate electrode 230 is shown as a single film in the drawings, this is merely an example, and it goes without saying that they may each be formed by stacking a plurality of conductive films. For example, each of the first gate electrode 130 and the second gate electrode 230 may include a work function adjustment film that adjusts the work function, and a filling conductive film that fills a space formed by the work function adjustment film. The work function adjustment film may include, for example, TiN, TaN, TiC, TaC, TiAlC and/or a combination thereof. The filling conductive film may include, for example, W and/or Al.

In some embodiments, each of the first gate electrode 130 and the second gate electrode 230 may include different conductive materials from each other. For example, each of the first gate electrode 130 and the second gate electrode 230 may include work function adjustment films of different conductivity types from each other. As an example, the first gate electrode 130 may include a p-type work function adjustment film, and the second gate electrode 230 may include an n-type work function adjustment film.

Although the first gate electrode 130 and the second gate electrode 230 are shown to be in direct contact with each other in FIG. 4, this is merely an example. If necessary, the first gate electrode 130 and the second gate electrode 230 may be electrically separated. For example, unlike the shown example, the intermediate insulating pattern 115 may extend in the third direction Y and (electrically) separate the first gate electrode 130 and the second gate electrode 230.

The gate spacer 140 may extend along the side face of the first gate electrode 130 and the side face of the second gate electrode 230. Each of the lower active patterns A11 and A12 and the upper active patterns A21 and A22 may extend in the second direction X and penetrate (extend in) the gate spacer 140. The gate spacer 140 may include an insulating material, for example, but not limited to, silicon oxide, silicon nitride, silicon oxynitride, silicon oxycarbide, silicon boron nitride, silicon boron carbonitride, silicon oxycarbonitride and/or a combination thereof.

In some embodiments, a part of the gate dielectric film 120 may be interposed between the second gate electrode 230 and the gate spacer 140. For example, the gate dielectric film 120 may further extend along the inner face of the gate spacer 140.

The gate capping film 145 may extend along (on) the upper face of the second gate electrode 230. The gate capping film 145 may include an insulating material, for example, but not limited to, silicon oxide, silicon nitride, silicon oxynitride, silicon oxycarbide, silicon boron nitride, silicon boron carbonitride, silicon oxycarbonitride and/or a combination thereof.

The cut pattern 150 may extend long in the second direction X. The cut pattern 150 may be spaced apart from the lower active patterns A11 and A12 and the upper active patterns A21 and A22 in the third direction Y. The plurality of cut patterns 150 may be spaced apart from each other in the third direction Y.

The gate structures G11, G12, G21, G22, G31 and G32 may be cut by the cut pattern 150. For example, the cut pattern 150 may extend in the second direction X between the first lower active pattern A11 and the second lower active pattern A12, and between the first upper active pattern A21 and the second upper active pattern A22. Such a cut pattern 150 may separate the first gate structure G11 and the second gate structure G12 in the third direction Y, may separate the third gate structure G21 and the fourth gate structure G22 in the third direction Y, and may separate the fifth gate structure G31 and the sixth gate structure G32 in the third direction Y.

In some embodiments, the cut pattern 150 may include a liner insulating film 152 and a filling insulating film 154 that are sequentially stacked on the side faces of each of the gate structures G11, G12, G21, G22, G31 and G32.

The liner insulating film 152 may be interposed between each of the gate structures G11, G12, G21, G22, G31 and G32 and the filling insulating film 154. In some embodiments, the first gate electrode 130 and the second gate electrode 230 may be in direct contact with the liner insulating film 152. The liner insulating film 152 may include, for example, but not limited to, silicon oxide, silicon oxynitride, silicon oxycarbonitride and/or a combination thereof. As an example, the liner insulating film 152 may include a silicon nitride film.

The filling insulating film 154 may fill a region of the cut pattern 150 that remains after the liner insulating film 152 is formed. The filling insulating film 154 may include, for example, but not limited to, silicon oxide, silicon oxynitride, silicon oxycarbonitride and/or a combination thereof. As an example, the filling insulating film 154 may include a silicon oxide film.

The lower source/drain patterns 160A and 160B may be formed inside (on) the lower active patterns A11 and A12 on the side faces of the gate structures G11, G12, G21, G22, G31 and G32. The lower source/drain patterns 160A and 160B may include a first lower source/drain pattern 160A and a second lower source/drain pattern 160B. The first lower active pattern A11 may penetrate (extend in) the first gate electrode 130, and may be (electrically) connected to the first lower source/drain pattern 160A. The second lower active pattern A12 may penetrate (extend in) the first gate electrode 130, and may be (electrically) connected to the second lower source/drain pattern 160B. The lower source/drain patterns 160A and 160B may be separated from the first gate electrode 130 by the gate spacer 140 and/or the gate dielectric film 120.

In some embodiments, each of the lower source/drain patterns 160A and 160B may include an epitaxial layer doped with impurities. For example, the first lower source/drain pattern 160A may include an epitaxial pattern that is grown from the first lower active pattern A11 by an epitaxial growth method. For example, the second lower source/drain pattern 160B may include an epitaxial pattern that is grown from the second lower active pattern A12 by the epitaxial growth method.

When the lower active patterns A11 and A12 are channel regions of PFET, each of the lower source/drain patterns 160A and 160B may include a P-type impurity (e.g., B, In, Ga, and/or Al) and/or an impurity for preventing diffusion of the P-type impurity.

In some embodiments, the first lower source/drain pattern 160A may include a first lower epitaxial pattern 1601 on one side of the first gate structure G11 and a second lower epitaxial pattern 1602 on the other side (e.g., the opposite side in the second direction X) of the first gate structure G11. For example, the first lower epitaxial pattern 1601 may be interposed between the first gate structure G11 and the third gate structure G21 (in the second direction X). For example, the second lower epitaxial pattern 1602 may be interposed between the first gate structure G11 and the fifth gate structure G31 (in the second direction X).

The first etch stop layer 165 may be formed on the lower source/drain patterns 160A and 160B. The first etch stop layer 165 may extend along profiles of the surfaces of each of the lower source/drain patterns 160A and 160B. In some embodiments, the first etch stop layer 165 may further extend along (on) the first face 102a of the substrate 102. The first etch stop layer 165 may include, for example, but not limited to, silicon nitride (SiN), silicon oxynitride (SiON), silicon oxycarbonitride (SiOCN), silicon boronitride (SiBN), silicon oxyboronitride (SiOBN), silicon oxycarbide (SiOC) and/or a combination thereof.

The first interlayer insulating film 190 may be formed on the first etch stop layer 165. The first interlayer insulating film 190 may be formed to fill the space on the first etch stop layer 165. The first interlayer insulating film 190 may include, for example, but not limited to, silicon oxide, silicon nitride, silicon oxynitride, silicon oxycarbide, silicon boron nitride, silicon boron carbonitride, silicon oxycarbonitride, a low-dielectric constant material having a dielectric constant smaller than that of silicon oxide and/or a combination thereof. The low-dielectric constant material may include, for example, but not limited to, FOX (Flowable Oxide), TOSZ (Torene SilaZene), USG (Undoped Silica Glass), BSG (Borosilica Glass), PSG (PhosphoSilica Glass), BPSG (BoroPhosphoSilica Glass), PETEOS (Plasma Enhanced Tetra Ethyl Ortho Silicate), FSG (Fluoride Silicate Glass), CDO (Carbon Doped silicon Oxide), Xerogel, Aerogel, Amorphous Fluorinated Carbon, OSG (Organo Silicate Glass), Parylene, BCB (bis-benzocyclobutenes), SiLK, polyimide, porous polymeric material, and/or combinations thereof.

The upper source/drain patterns 260A and 260B may be formed inside (on) the upper active patterns A21 and A22 on the side faces of the gate structures G11, G12, G21, G22, G31 and G32. The upper source/drain patterns 260A and 260B may include a first upper source/drain pattern 260A and a second upper source/drain pattern 260B. The first upper active pattern A21 may penetrate (extend in) the second gate electrode 230, and may be (electrically) connected to the first upper source/drain pattern 260A. The second upper active pattern A22 may penetrate (extend in) the second gate electrode 230, and may be (electrically) connected to the second upper source/drain pattern 260B. The upper source/drain patterns 260A and 260B may be separated from the second gate electrode 230 by the gate spacer 140 and/or the gate dielectric film 120.

In some embodiments, each of the upper source/drain patterns 260A and 260B may include an epitaxial layer doped with impurities. For example, the first upper source/drain pattern 260A may include an epitaxial pattern that is grown from the first upper active pattern A21 by an epitaxial growth method. For example, the second upper source/drain pattern 260B may include an epitaxial pattern which is grown from the second upper active pattern A22 by the epitaxial growth method.

When the upper active patterns A21 and A22 are channel regions of NFET, each of the upper source/drain pattern 260A and 260B may include an N-type impurity (e.g., P, Sb, and/or As) and/or an impurity for preventing diffusion of the N-type impurity.

In some embodiments, the first upper source/drain pattern 260A may include a first upper epitaxial pattern 2601 on one side of the first gate structure G11, and a second upper epitaxial pattern 2602 on the other side (e.g., the opposite side in the second direction X) of the first gate structure G11. For example, the first upper epitaxial pattern 2601 may be interposed between the first gate structure G11 and the third gate structure G21 (in the second direction X). For example, the second upper epitaxial pattern 2602 may be interposed between the first gate structure G11 and the fifth gate structure G31 (in the second direction X).

The second etch stop layer 265 may be formed on the upper source/drain patterns 260A and 260B. The second etch stop layer 265 may extend along profiles of the surfaces of each of the upper source/drain patterns 260A and 260B. In some embodiments, the second etch stop layer 265 may further extend along (on) the upper face of the first interlayer insulating film 190. The second etch stop layer 265 may be provided as an etch stop layer in an etching process for forming front source/drain contacts FCA. The second etch stop layer 265 may include, for example, but not limited to, silicon nitride (SiN), silicon oxynitride (SiON), silicon oxycarbonitride (SiOCN), silicon boronitride (SiBN), silicon oxyboronitride (SiOBN), silicon oxycarbide (SiOC) and/or a combination thereof.

The second interlayer insulating film 290 may be formed on the second etch stop layer 265. The second interlayer insulating film 290 may be formed to fill the space above the second etch stop layer 265. The second interlayer insulating film 290 may include, for example, but not limited to, silicon oxide, silicon nitride, silicon oxynitride, silicon oxycarbide, silicon boron nitride, silicon boron carbonitride, silicon oxycarbonitride, a low-dielectric constant material having a dielectric constant smaller than that of silicon oxide and/or a combination thereof.

The front source/drain contacts FCA may be formed on the upper faces of the upper source/drain patterns 260A and 260B. The front source/drain contacts FCA may be (electrically) connected to the upper source/drain patterns 260A and 260B. For example, the front source/drain contacts FCA may each extend in the first direction Z and penetrate (extend into) the second interlayer insulating film 290 and the second etch stop layer 265. In some embodiments, the front source/drain contacts FCA may extend into the upper source/drain patterns 260A and 260B.

The front wiring structure FS may be formed on the first face 102a of the substrate 102. For example, the front wiring structure FS may be formed on the upper face of the second interlayer insulating film 290. The front wiring structure FS may include a front inter-wiring insulating film FID, multi-layer front wiring patterns FM inside the front inter-wiring insulating film FID, and front via patterns FV (electrically) connected to the front wiring patterns FM. The number of layers, number, placement, and the like of the front inter-wiring insulating film FID, the front wiring patterns FM, and the front via patterns FV shown in the drawings are mere examples and are not limited to those shown in the drawings.

Although not specifically shown, each of the front wiring patterns FM and the front via patterns FV may include a barrier conductive film and a filling conductive film. The barrier conductive film may include a metal and/or a metal nitride for preventing the diffusion of the filling conductive film. The barrier conductive film may include, for example, but not limited to, titanium (Ti), tantalum (Ta), tungsten (W), nickel (Ni), cobalt (Co), platinum (Pt), alloys thereof, and/or nitrides thereof. The filling conductive film may include, for example, but not limited to, aluminum (Al), copper (Cu), tungsten (W), molybdenum (Mo), cobalt (Co), ruthenium (Ru), and/or alloys thereof.

The front wiring structure FS may provide a signal line and/or a power line for electronic elements (e.g., a field effect transistor) on the first face 102a of the substrate 102. For example, the front wiring structure FS may be electrically connected to the upper source/drain patterns 260A and 260B and/or the second gate electrode 230. As an example, as shown in FIG. 6, the second upper epitaxial pattern 2602 may be (electrically) connected to at least one of the front via patterns FV through at least one of the front source/drain contacts FCA.

In some embodiments, as shown in FIG. 4, a gate contact CB may be formed on the second gate electrode 230. The gate contact CB penetrates (extends in) the gate capping film 145 and, may (electrically) connect the second gate electrode 230 to some of the front wiring patterns FM.

The back source/drain contacts BCA may be formed on the lower faces of the lower source/drain patterns 160A and 160B. The back source/drain contacts BCA may be (electrically) connected to the lower source/drain patterns 160A and 160B. For example, each of the back source/drain contacts BCA may extend in the first direction Z and penetrate (extend in) the substrate 102.

In some embodiments, a contact spacer 108 may be formed between the substrate 102 and each back source/drain contact BCA. The contact spacer 108 may extend along (may be on) a side face of each back source/drain contact BCA. The contact spacer 108 may include an insulating material, for example, but not limited to, silicon oxide, silicon nitride, silicon oxynitride, silicon oxycarbide, silicon boron nitride, silicon boron carbonitride, silicon oxycarbonitride and/or a combination thereof.

The back connecting contacts BCM may be formed on the second face 102b of the substrate 102. The back connecting contacts BCM may be (electrically) connected to the back source/drain contacts BCA. For example, a third interlayer insulating film 109 may be formed on the second face 102b of the substrate 102. The back connecting contacts BCM may extend in the first direction Z and penetrate (extend in) the third interlayer insulating film 109.

The back wiring structure BS may be formed on the second face 102b of the substrate 102. For example, the back wiring structure BS may be formed on the lower face of the third interlayer insulating film 109. The back wiring structure BS may include a back inter-wiring insulating film BID, multi-layer back wiring patterns BM inside the back inter-wiring insulating film BID, and back via patterns BV (electrically) connected to the back wiring patterns BM. The number of layers, number, and placement of the back inter-wiring insulating film BID, the back wiring patterns BM, and the back via patterns BV shown in the drawings are mere examples and are not limited to those shown in the drawings.

Although not specifically shown, each of the back wiring patterns BM and the back via patterns BV may include a barrier conductive film and a filling conductive film. The barrier conductive film may include a metal and/or a metal nitride for preventing the diffusion of the filling conductive film. The barrier conductive film may include, for example, but not limited to, titanium (Ti), tantalum (Ta), tungsten (W), nickel (Ni), cobalt (Co), platinum (Pt), alloys thereof, and/or nitrides thereof. The filling conductive film may include, for example, but not limited to, aluminum (Al), copper (Cu), tungsten (W), molybdenum (Mo), cobalt (Co), ruthenium (Ru), and/or alloys thereof.

The back wiring structure BS may provide a signal line and/or a power line for electronic elements (e.g., a field effect transistor) on the second face 102b of the substrate 102. For example, the back wiring structure BS may be electrically connected to the lower source/drain patterns 160A and 160B and/or the first gate electrode 130. As an example, as shown in FIG. 5, the first lower epitaxial pattern 1601 may be (electrically) connected to at least one of the back via patterns BV through at least one of the back source/drain contacts BCA and at least one of the back connecting contacts BCM.

The via structure 180 may be formed inside the cut pattern 150. The via structure 180 may be spaced apart from the lower active patterns A11 and A12 and the upper active patterns A21 and A22 in the third direction Y. The via structure 180 may include a connecting part 182, a first pillar part 184, and a second pillar part 186. The connecting part 182, the first pillar part 184, and the second pillar part 186 may be integrally formed to form the via structure 180. For example, the connecting part 182, the first pillar part 184, and the second pillar part 186 may be connected to each other without a (visible) boundary therebetween.

The connecting part 182 may overlap the first gate structure G11 in the third direction Y. The connecting part 182 may extend in the second direction X and connect the first pillar part 184 and the second pillar part 186. In some embodiments, the connecting part 182 may overlap the intermediate insulating pattern 115 in the third direction Y.

The first pillar part 184 may overlap the first upper epitaxial pattern 2601 in the third direction Y. For example, the first pillar part 184 may extend upward (e.g., in a direction toward the front wiring structure FS) from an upper face of one side (a first side in the second direction X) of the connecting part 182. In some embodiments, the first pillar part 184 may not overlap the second upper epitaxial pattern 2602 in the third direction Y. In some embodiments, the first pillar part 184 may not overlap the second gate electrode 230 of the first gate structure G11 in the third direction Y.

The connecting part 182 and the first pillar part 184 may define a first via recess 180r1 of the via structure 180. The first via recess 180r1 may extend downward (e.g., a direction toward the back wiring structure BS) from the upper face of the via structure 180. The side face of the first via recess 180r1 may be defined by the inner face (the side face) of the first pillar part 184, and the lower face of the first via recess 180r1 may be defined by the upper face of the connecting part 182. In some embodiments, the first via recess 180r1 may overlap the second upper epitaxial pattern 2602 in the third direction Y. In some embodiments, the first via recess 180r1 may overlap the second gate electrode 230 of the first gate structure G11 in the third direction Y.

In some embodiments, as shown in FIG. 3, the first via recess 180r1 may include a curved face that connects the lower face of the first via recess 180r1 and the side face of the first via recess 180r1. For example, in the region adjacent to the connecting part 182, the width of the first pillar part 184 in the second direction X may gradually decrease as it goes away from the connecting part 182. This may be due to the characteristics of the recess process for forming the first via recess 180r1.

The second pillar part 186 may overlap the second lower epitaxial pattern 1602 in the third direction Y. For example, the second pillar part 186 may extend downward (e.g., in the direction toward the back wiring structure BS) from the lower face of the other side (a second side that is opposite to the first side in the second direction X) of the connecting part 182. In some embodiments, the second pillar part 186 may not overlap the first lower epitaxial pattern 1601 in the third direction Y. In some embodiments, the second pillar part 186 may not overlap the first gate electrode 130 of the first gate structure G11 in the third direction Y.

The connecting part 182 and the second pillar part 186 may define a second via recess 180r2 of the via structure 180. The second via recess 180r2 may extend upward (e.g., in the direction toward the front wiring structure FS) from the lower face of the via structure 180. The side face of the second via recess 180r2 may be defined by the inner face (a side face) of the second pillar part 186, and the upper face of the second via recess 180r2 may be defined by the lower face of the connecting part 182. In some embodiments, the second via recess 180r2 may overlap the first lower epitaxial pattern 1601 in the third direction Y. In some embodiments, the second via recess 180r2 may overlap the first gate electrode 130 of the first gate structure G11 in the third direction Y.

In some embodiments, as shown in FIG. 3, the second via recess 180r2 may include a curved face that connects the upper face of the second via recess 180r2 and the side face of the second via recess 180r2. For example, in the region adjacent to the connecting part 182, the width of the second pillar part 186 in the second direction X may gradually decrease as it goes away from the connecting part 182. This may be due to the characteristics of the recess process for forming the second via recess 180r2.

The filling insulating film 154 may fill the first via recess 180r1 and the second via recess 180r2. For example, the filling insulating film 154 may include a main filling film 154a, a first recess filling film 154b, and a second recess filling film 154c. The first recess filling film 154b may be interposed between the main filling film 154a and the first pillar part 184 in the second direction X. The first recess filling film 154b may fill the first via recess 180r1. The second recess filling film 154c may be interposed between the main filling film 154a and the second pillar part 186 in the second direction X. The second recess filling film 154c may fill the second via recess 180r2. In FIG. 3, although a boundary between the main filling film 154a and the first recess filling film 154b, and a boundary between the main filling film 154a and the second recess filling film 154c are shown to exist, this is a mere example. In some cases, the boundary between the main filling film 154a and the first recess filling film 154b and/or the boundary between the main filling film 154a and the second recess filling film 154c may not exist (may not be visible).

In some embodiments, the height of the lower face of the first via recess 180r1 may be the same as or lower than the height of the upper face of the intermediate insulating pattern 115. In some embodiments, the lower face of the first via recess 180r1 may be coplanar with the lower face of the second upper epitaxial pattern 2602. Herein, the term “level”, “vertical level”, “height”, or the like may refer to a relative location with respect to a reference element in the first direction Z. For example, a level, a vertical level, height, or the like may be a distance from the lower face of the back inter-wiring insulating film BID in the first direction Z. For example, a higher level may mean a farther distance from the lower face of the back inter-wiring insulating film BID in the first direction Z, and a lower level may mean a closer distance to the lower face of the back inter-wiring insulating film BID in the first direction Z.

In some embodiments, the height of the upper face of the second via recess 180r2 may be the same as or higher than the height of the lower face of the intermediate insulating pattern 115. In some embodiments, the upper face of the second via recess 180r2 may be coplanar with the upper face of the first lower epitaxial pattern 1601.

In some embodiments, the first pillar part 184 and the second pillar part 186 may not overlap in the first direction Z. For example, as shown in FIG. 3, a part of the first via recess 180r1 adjacent to the first pillar part 184 and a part of the second via recess 180r2 adjacent to the second pillar part 186 may overlap in the first direction Z.

The via structure 180 may (electrically) connect the first region I and the second region II across at least one of the gate structures G11, G12, G21, G22, G31 and G32. For example, as shown, the via structure 180 may (electrically) connect the first upper epitaxial pattern 2601 and the second lower epitaxial pattern 1602 across the first gate structure G11. For example, a first connecting pattern FCA1 that extends in the third direction Y and (electrically) connects the first upper epitaxial pattern 2601 and the first pillar part 184 may be formed. Also, for example, a second connecting pattern BCM1 that extends in the third direction Y and (electrically) connects the second lower epitaxial pattern 1602 and the second pillar part 186 may be formed. Accordingly, the first upper epitaxial pattern 2601 and the second lower epitaxial pattern 1602 may be electrically connected.

In some embodiments, the first connecting pattern FCA1 may be in direct contact with the side face of the first pillar part 184, as shown in FIG. 5. In some embodiments, the first connecting pattern FCA1 may be included in the front source/drain contacts FCA. For example, the first connecting pattern FCA1 may be formed at the same level as other front source/drain contacts FCA that are not connected to the first upper epitaxial pattern 2601. In this specification, the term “same level” (e.g., same level of elements) may mean levels (e.g., elements) formed by the same fabricating process.

In some embodiments, as shown in FIG. 6, the second connecting pattern BCM1 may be in direct contact with the lower face of the second pillar part 186. In some embodiments, the second connecting pattern BCM1 may be included in the back connecting contacts BCM. For example, the second connecting pattern BCM1 may be formed at the same level as other back connecting contacts BCM that are not connected to the second lower epitaxial pattern 1602.

In some embodiments, the via structure 180 may be electrically connected to the front wiring structure FS. For example, the first connecting pattern FCA1 may be (electrically) connected to some of the front via patterns FV.

As the semiconductor devices gradually become highly integrated, individual circuit patterns are becoming finer to implement more elements in the same area. For this reason, a semiconductor device using a stacked multi-gate transistor in which a multi-gate transistor of an upper region (e.g., the second region II) is stacked on a multi-gate transistor of a lower region (e.g., the first region I) is being studied. However, such a semiconductor device has a problem of difficulty in improving the degree of integration due to the complexity of the circuit patterns.

For example, depending on the design, a via that connects the lower region and the upper region across the gate may be required. However, such a via may cause a decrease in performance of the semiconductor device by increasing the parasitic capacitance with the gate and/or the source/drain pattern opposite to the via.

In contrast, in the semiconductor device according to some embodiments, the via structure 180 that (electrically) connects the first region I and the second region II across the first gate structure G11 may reduce parasitic capacitance. Specifically, as described above, the via structure 180 may include a first via recess 180r1 that overlaps the first gate structure G11 and/or the second upper epitaxial pattern 2602 in the third direction Y. Furthermore, as described above, the via structure 180 may include a second via recess 180r2 that overlaps the first gate structure G11 and/or the first lower epitaxial pattern 1601 in the third direction Y. Such a via structure 180 may reduce the parasitic capacitance, by reducing the opposite area with the first gate structure G11, the second upper epitaxial pattern 2602, and/or the first lower epitaxial pattern 1601.

Also, the via structure 180 may have a connecting part 182, a first pillar part 184, and a second pillar part 186 that are defined by the first via recess 180r1 and the second via recess 180r2. Because the connecting part 182, the first pillar part 184, and the second pillar part 186 may be integrally formed, deterioration of electrical resistance due to interfacial resistance may be reduced (e.g., prevented). A semiconductor device having improved performance and degree of integration can be provided, accordingly.

In FIGS. 1 to 6, although the via structure 180 has only been described above to cross gate structures (i.e., the first gate structure G11 and the second gate structure G12) of one row, this is merely an example. A person having ordinary skill in the art to which the present inventive concept pertains will understand that the connecting part 182 of the via structure 180 may also intersect gate structures of two or more rows to connect the first region I and the second region II.

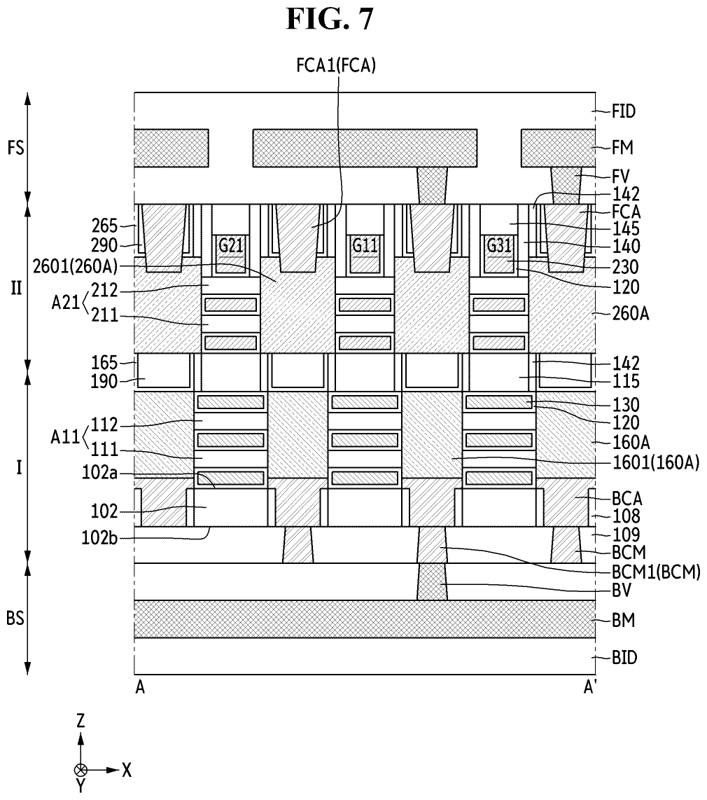

FIG. 7 is a schematic cross-sectional view for explaining a semiconductor device according to some embodiments. For convenience of explanation, repeated parts of contents explained above using FIGS. 1 to 6 may be briefly explained or omitted. For reference, FIG. 7 is another schematic cross-sectional view taken along A-A′ of FIG. 1.

Referring to FIGS. 1 and 7, in the semiconductor device according to some embodiments, the via structure 180 may be electrically connected to the back wiring structure BS. For example, the second connecting pattern BCM1 may be (electrically) connected to some of the back via patterns BV.

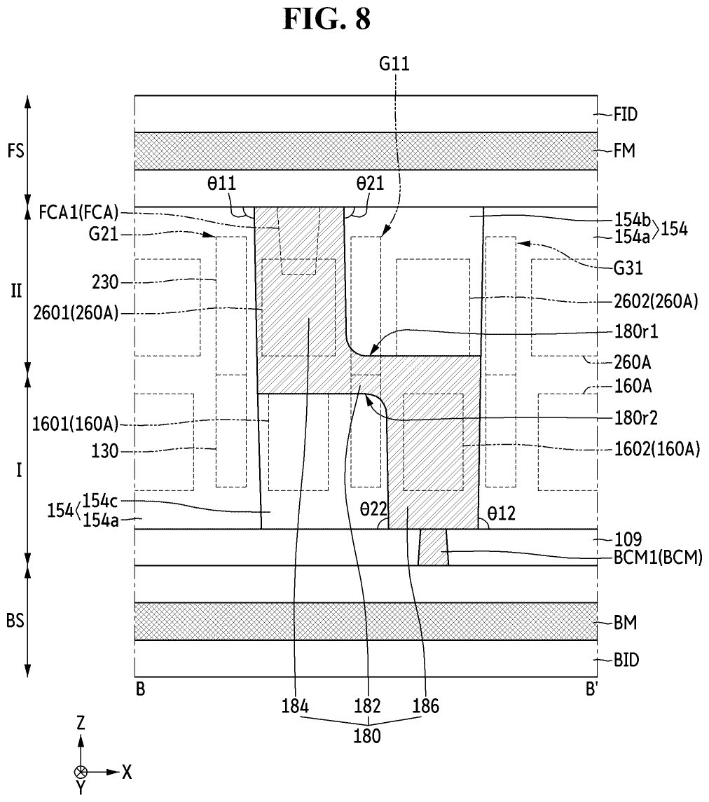

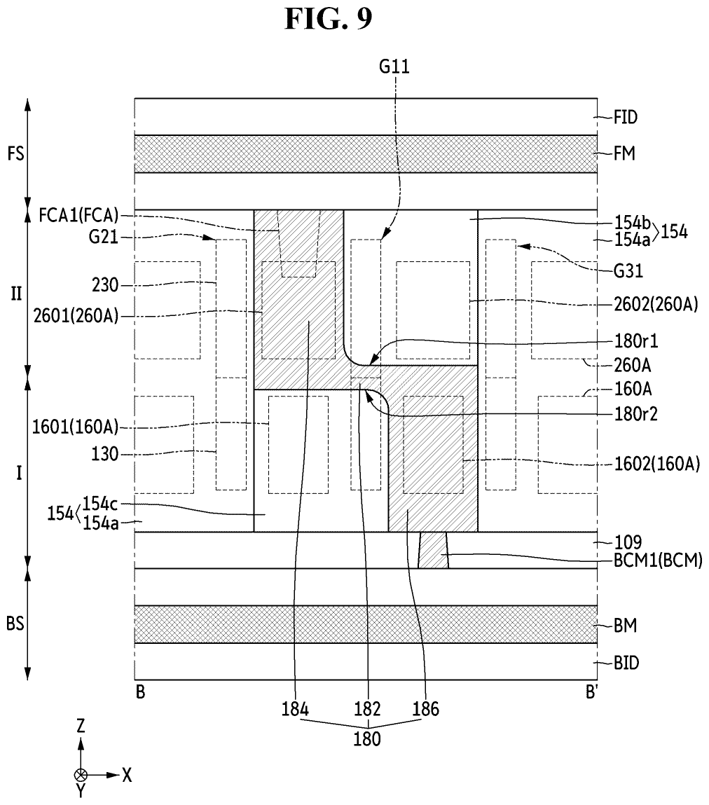

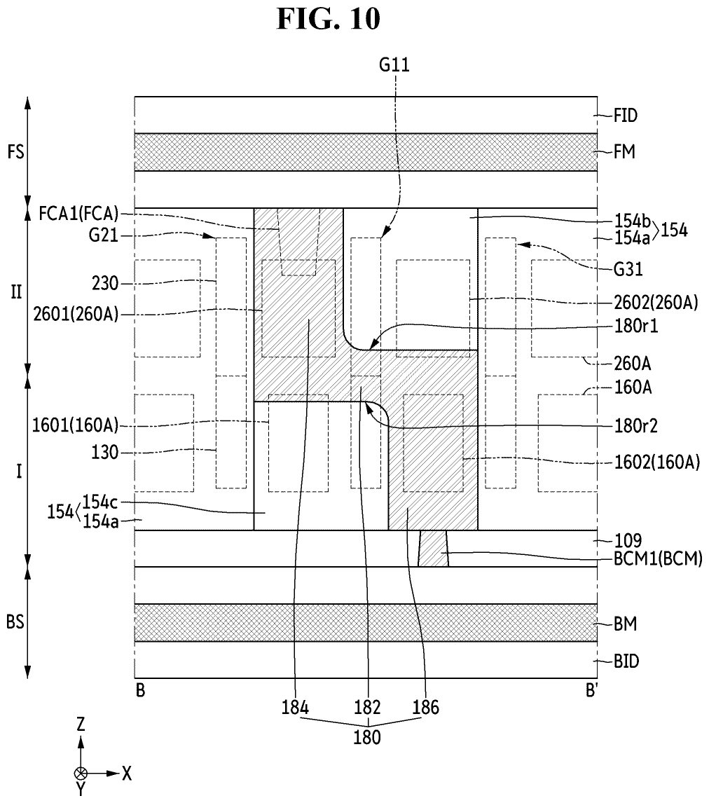

FIGS. 8 to 11 are various schematic cross-sectional views for explaining a semiconductor device according to some embodiments. For convenience of explanation, repeated parts of contents explained above using FIGS. 1 to 7 may be briefly explained or omitted. For reference, FIGS. 8 to 11 are another schematic cross-sectional views taken along B-B′ of FIG. 1, respectively.

Referring to FIGS. 1 and 8, in the semiconductor device according to some embodiments, the first pillar part 184 and/or the second pillar part 186 may have an inclined face (an inclined side surface).

For example, the outer face of the first pillar part 184 opposite to (facing) the main filling film 154a may form a first outer angle θ11 that is not a right angle with the upper face of the main filling film 154a. For example, the outer face of the second pillar part 186 opposite to the main filling film 154a may form a second outer angle θ12 that is not a right angle with the lower face of the main filling film 154a. In some embodiments, the first outer angle θ11 may be an obtuse angle, and the second outer angle θ12 may be an acute angle. This may be due to the characteristics of the etching process for forming the via structure 180.

For example, the inner face of the first pillar part 184 opposite to (facing) the first recess filling film 154b may form a third outer angle θ21 that is not a right angle with the upper face of the first recess filling film 154b. In some embodiments, the third outer angle θ21 may be an acute angle. This may be due to the characteristics of the recess process for forming the first via recess 180r1.

For example, the inner face of the second pillar part 186 opposite to (facing) the second recess filling film 154c may form a fourth outer angle θ22 that is not a right angle with the lower face of the second recess filling film 154c. In some embodiments, the fourth exterior angle θ22 may be an acute angle. This may be due to the characteristics of the recess process for forming the second via recess 180r2.

Referring to FIGS. 1, 2, and 9, in the semiconductor device according to some embodiments, the height of the lower face of the first via recess 180r1 may be lower than the height of the lower face of the second upper epitaxial pattern 2602, and/or the height of the upper face of the second via recess 180r2 may be higher than the height of the upper face of the first lower epitaxial pattern 1601.

For example, the height of the lower face of the first via recess 180r1 may be lower than the height of the upper face of the intermediate insulating pattern 115, or the height of the upper face of the second via recess 180r2 may be lower than the upper face of the intermediate insulating pattern 115. Such a via structure 180 may further reduce the parasitic capacitance, by reducing an opposite area with the first gate structure G11, the second upper epitaxial pattern 2602, and/or the first lower epitaxial pattern 1601 compared to the via structure 180 of FIG. 3.

Referring to FIGS. 1, 2, and 10, in the semiconductor device according to some embodiments, the connecting part 182 may overlap the second upper epitaxial pattern 2602 and/or the first lower epitaxial pattern 1601 in the third direction Y.

For example, the height of the lower face of the first via recess 1 80r1 may be higher than the height of the lower face of the second upper epitaxial pattern 2602. In some embodiments, the height of the lower face of the first via recess 180r1 may be higher than the height of the upper face of the intermediate insulating pattern 115. Such a via structure 180 may have an increased volume compared to the via structure 180 of FIG. 3, and therefore, may have further reduced electrical resistance.

For example, the height of the upper face of the second via recess 180r2 may be lower than the height of the upper face of the first lower epitaxial pattern 1601. In some embodiments, the height of the upper face of the second via recess 180r2 may be lower than the height of the lower face of the intermediate insulating pattern 115. Such a via structure 180 may have an increased volume compared to the via structure 180 of FIG, and therefore, may have further reduced electrical resistance.

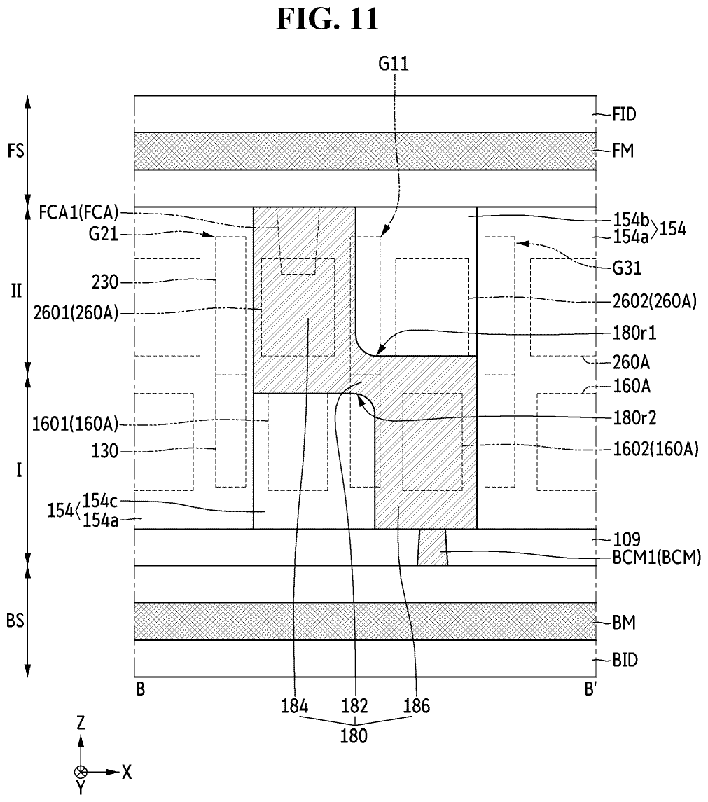

Referring to FIGS. 1 and 11, in the semiconductor device according to some embodiments, the first pillar part 184 and/or the second pillar part 186 may overlap the first gate structure G11 in the third direction Y.

For example, the inner face of the first pillar part 184 opposite to the first recess filling film 154b may overlap the second gate electrode 230 of the first gate structure G11 in the third direction Y. Such a first pillar part 184 has an increased volume compared to the via structure 180 of FIG. 3, and therefore, may have further reduced electrical resistance.

For example, the inner face of the second pillar part 186 opposite to (facing) the second recess filling film 154c may overlap the first gate electrode 130 of the first gate structure G11 in the third direction Y. Such a second pillar part 186 may have an increased volume compared to the via structure 180 of FIG. 3, and therefore, may have further reduced electrical resistance.

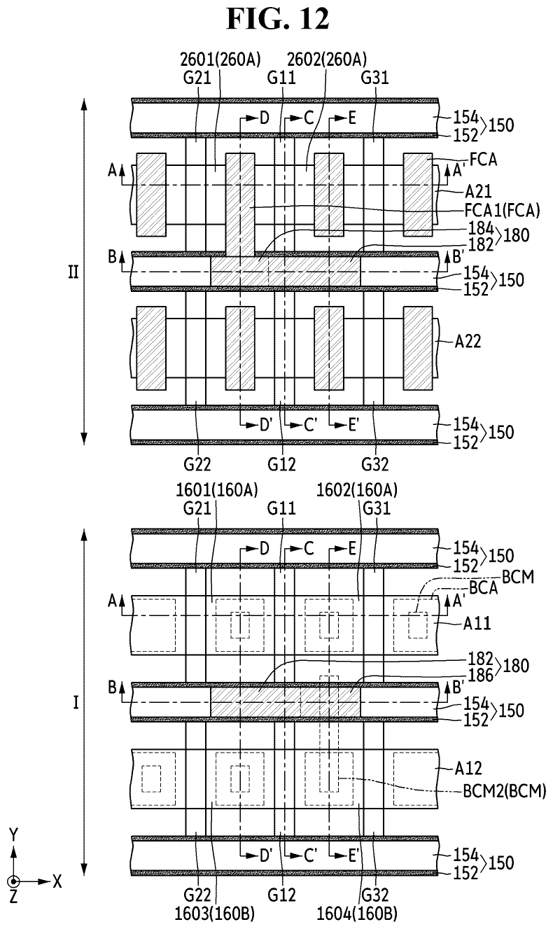

FIG. 12 is a layout diagram for explaining a semiconductor device according to some embodiments. For convenience of explanation, repeated parts of contents explained above using FIGS. 1 to 11 may be briefly explained or omitted.

Referring to FIG. 12, in the semiconductor device according to some embodiments, a via structure 180 may (electrically) connect the first upper source/drain pattern 260A and the second lower source/drain pattern 160B across at least one of the gate structures G11, G12, G21, G22, G31 and G32.

For example, the second lower source/drain pattern 160B may include a third lower epitaxial pattern 1603 on one side (e.g., a first side in the second direction X) of the first gate structure G11, and a fourth lower epitaxial pattern 1604 on the other side (e.g., a second side opposite to the first side in the second direction X) of the first gate structure G11. In addition, for example, a third connecting pattern BCM2 that extends in the third direction Y and (electrically) connects the fourth lower epitaxial pattern 1604 and the second pillar part 186 may be formed. Accordingly, the first upper epitaxial pattern 2601 and the fourth lower epitaxial pattern 1604 may be electrically connected.

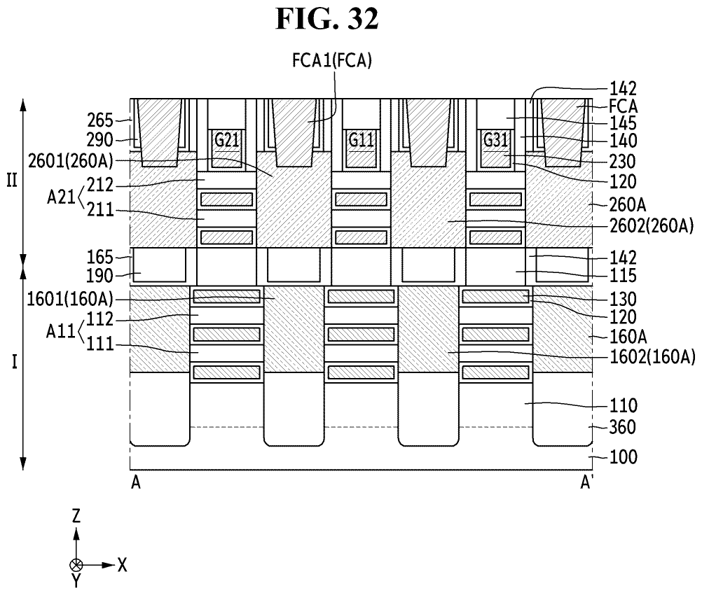

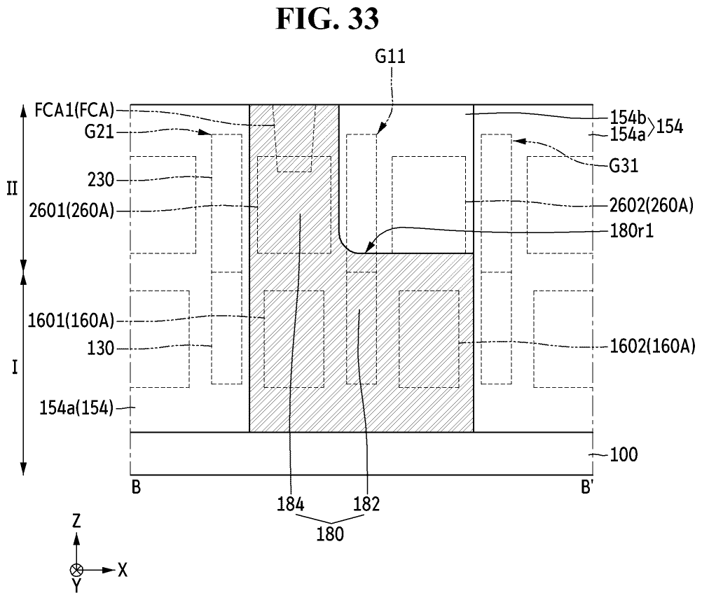

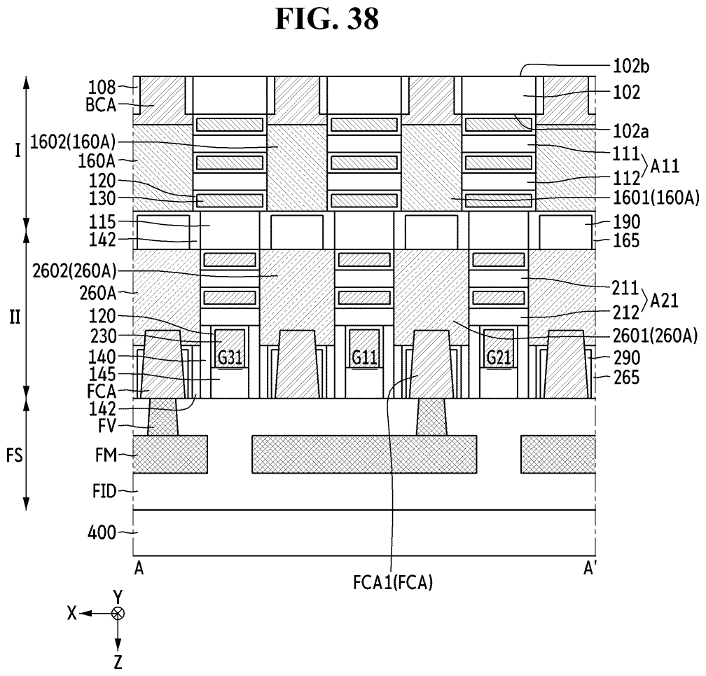

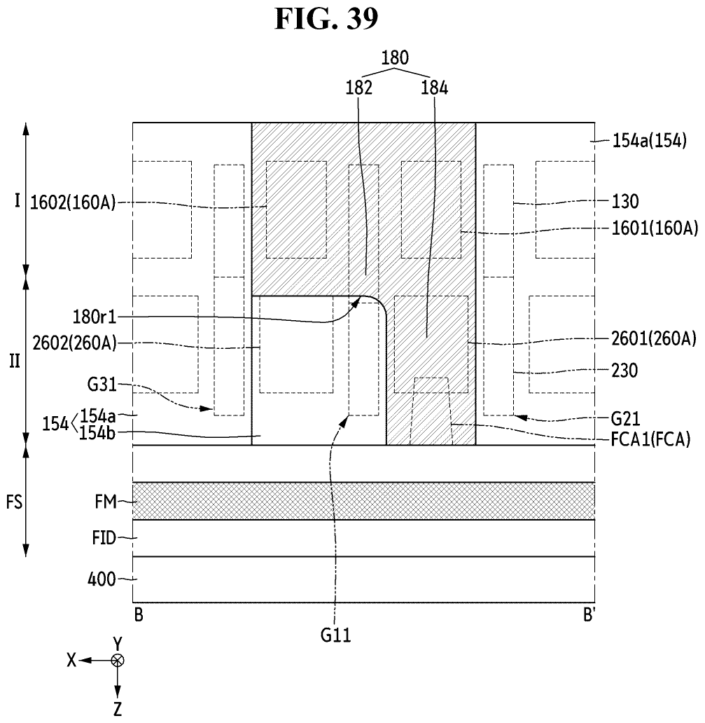

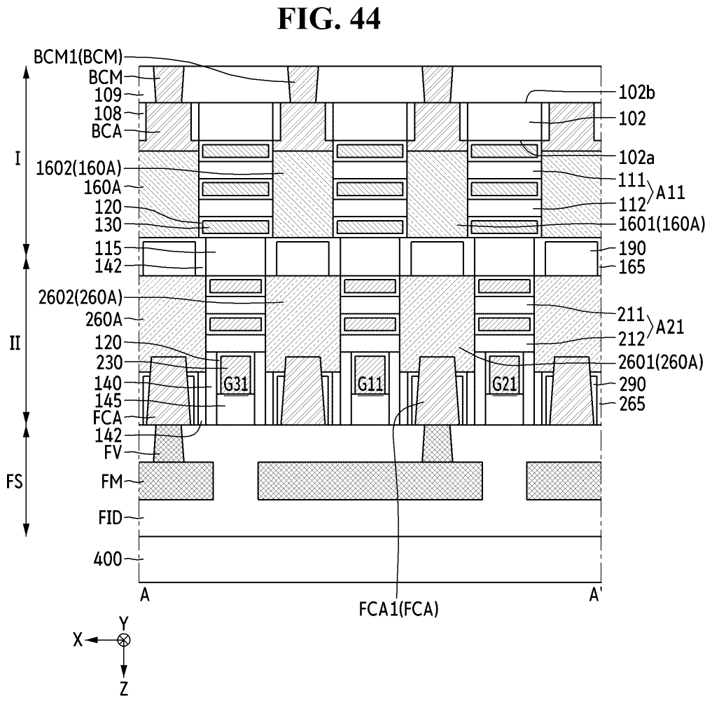

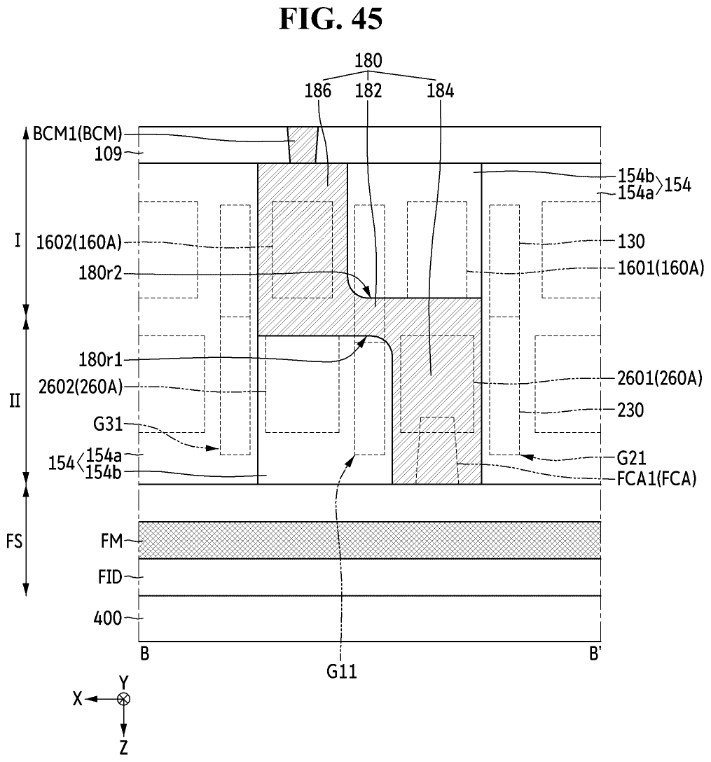

Hereinafter, a method for fabricating a semiconductor device according to example embodiments will be described referring to FIGS. 1 to 45.

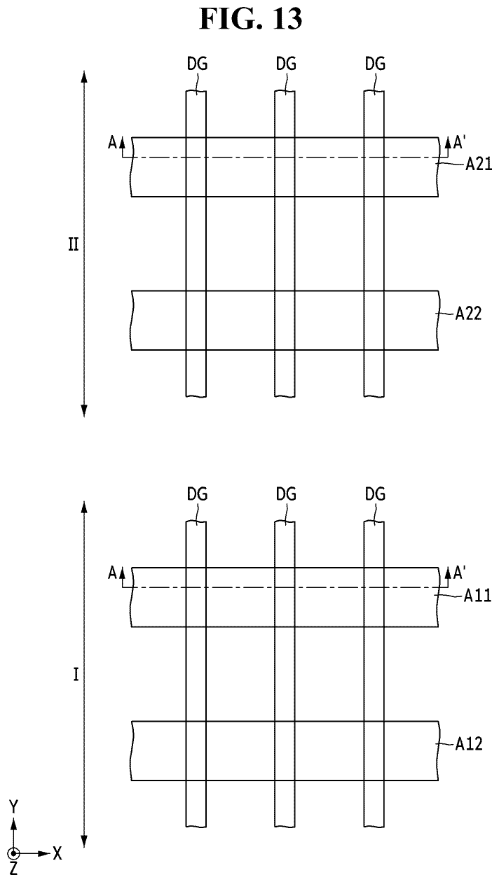

FIGS. 13 to 45 are intermediate stage diagrams for explaining the method for fabricating the semiconductor device according to some embodiments. For convenience of description, repeated parts of contents explained above using FIGS. 1 to 12 may be briefly described or omitted.

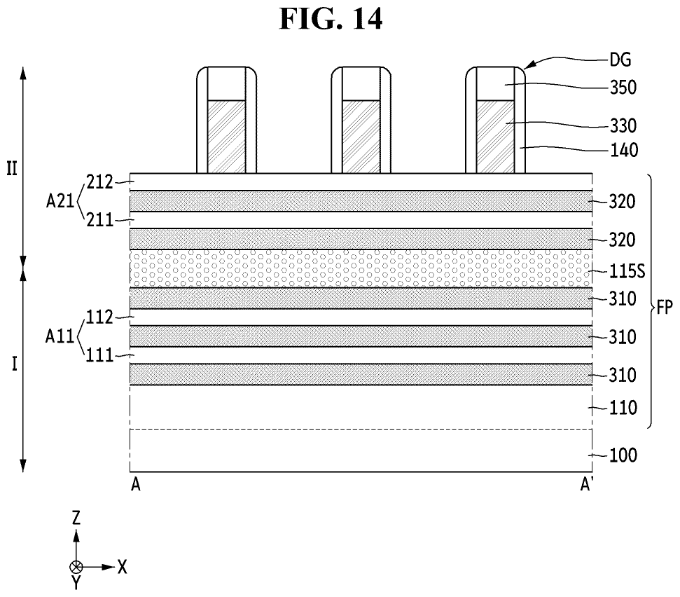

Referring to FIGS. 13 and 14, a fin structure FP and a dummy gate structure DG are formed on a base substrate 100.

The fin structure FP may extend long in the second direction X. The fin structure FP may include a fin pattern 110, lower bridge patterns 111 and 112, first sacrificial patterns 310, a sacrificial separation pattern 115S, upper bridge patterns 211 and 212, and second sacrificial patterns 320.

The fin pattern 110 may protrude from the upper face of the base substrate 100 and extend in the second direction X. The lower bridge patterns 111 and 112 and the first sacrificial patterns 310 may be alternately stacked on the fin pattern 110. The sacrificial separation pattern 115S may be stacked on the lower bridge patterns 111 and 112 and the first sacrificial patterns 310. The upper bridge patterns 211 and 212 and the second sacrificial patterns 320 may be alternately stacked on the sacrificial separation pattern 115S.

The first sacrificial patterns 310 and the second sacrificial patterns 320 may include a material having an etching selectivity with respect to the lower bridge patterns 111 and 112 and the upper bridge patterns 211 and 212. As an example, each of the lower bridge patterns 111 and 112 and the upper bridge patterns 211 and 212 may include a silicon film, and each of the first sacrificial patterns 310 and the second sacrificial patterns 320 may include a silicon germanium film.

The sacrificial separation pattern 115S may include a material having an etching selectivity with respect to the lower bridge patterns 111 and 112, the first sacrificial patterns 310, the upper bridge patterns 211 and 212, and the second sacrificial patterns 320. As an example, each of the first sacrificial patterns 310 and the second sacrificial patterns 320 may include a silicon germanium film including germanium (Ge) of a first concentration, and the sacrificial separation pattern 115S may include a silicon germanium film including germanium (Ge) of a second concentration different (e.g., greater) than the first concentration.

The dummy gate structure DG may be formed on the fin structure FP. The dummy gate structure DG may intersect (e.g., overlap in the first direction Z) the fin structure FP. For example, the dummy gate structure DG may extend long in the third direction Y.

The dummy gate structure DG may include a dummy gate electrode 330, a gate spacer 140, and a gate mask pattern 350. For example, a material film may be formed on the fin structure FP. Next, a gate mask pattern 350 extending long in the third direction Y may be formed on the material film. Next, a patterning process for patterning the material film using the gate mask pattern 350 as an etching mask may be performed, and a dummy gate electrode 330 may be formed from the material film. Next, a gate spacer 140 extending along the side face of the dummy gate electrode 330 may be formed.

The dummy gate electrode 330 may include a material having an etching selectivity with respect to the lower bridge patterns 111 and 112 and the upper bridge patterns 211 and 212. As an example, the dummy gate electrode 330 may include a polysilicon film.

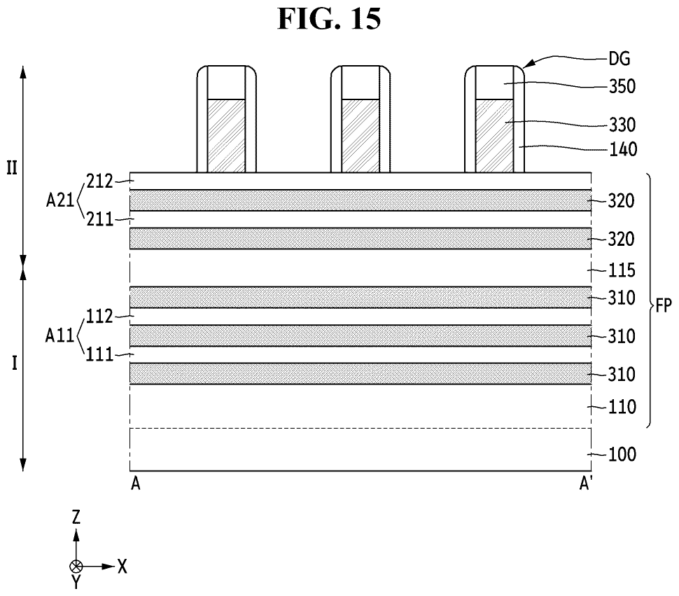

Referring to FIG. 15, an intermediate insulating pattern 115 may be formed.

For example, the sacrificial separation pattern 115S may be selectively removed. Next, an intermediate insulating pattern 115 which replaces the region in which the sacrificial separation pattern 115S is removed may be formed. Accordingly, the fin structure FP including the intermediate insulating pattern 115 may be provided.

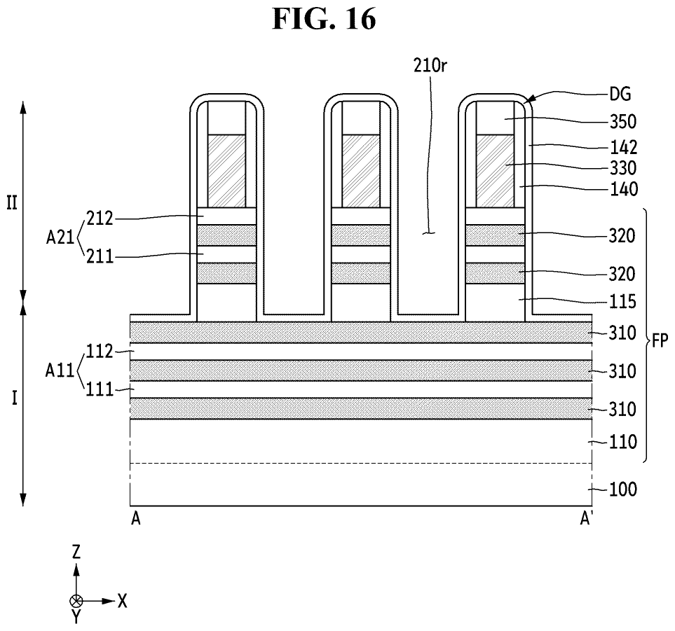

Referring to FIG. 16, a recess process may be performed on the upper bridge patterns 211 and 212 and the second sacrificial patterns 320, using the dummy gate structure DG.

As the recess process is performed, an upper source/drain recess 210r may be formed in the upper bridge patterns 211 and 212 and the second sacrificial patterns 320. In some embodiments, the lower face of the upper source/drain recess 210r may be lower than the upper face of the intermediate insulating pattern 115.

The spacer film 142 may then be formed. The spacer film 142 may conformally extend along the profile of the upper source/drain recess 210r. The spacer film 142 may include insulating materials, for example, but not limited to, silicon oxide, silicon nitride, silicon oxynitride, silicon oxycarbide, silicon boron nitride, silicon boron carbonitride, silicon oxycarbonitride, and/or a combination thereof.

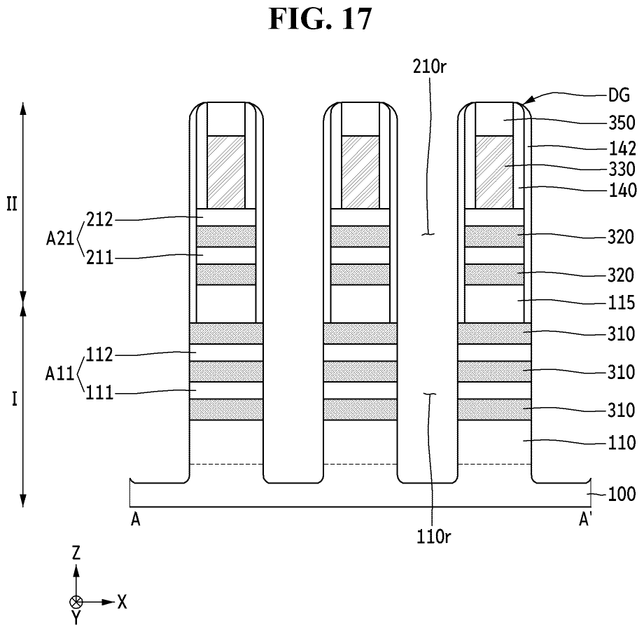

Referring to FIG. 17, a recess process may be performed on the lower bridge patterns 111 and 112 and the first sacrificial pattern 310, using the spacer film 142.

As the recess process is performed, the lower source/drain recess 110r may be formed inside the lower bridge patterns 111 and 112 and the first sacrificial patterns 310. In some embodiments, the lower face of the lower source/drain recess 110r may be lower than the upper face of the fin pattern 110.

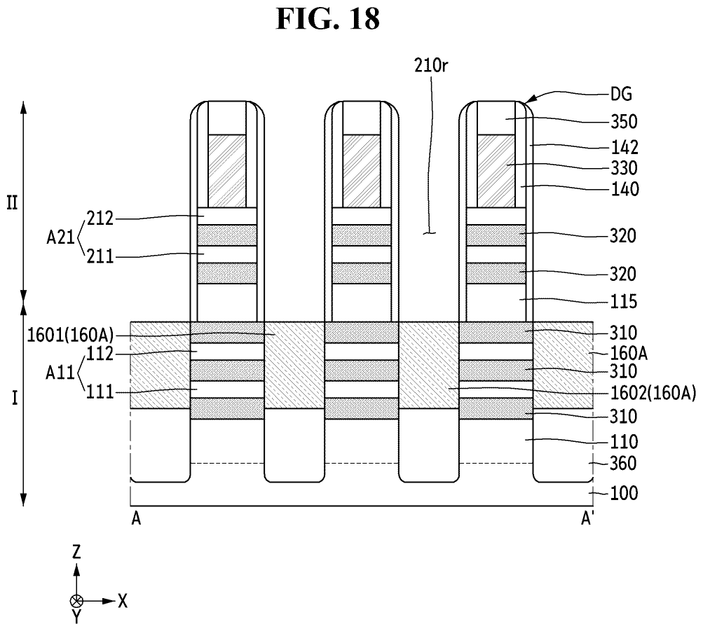

Referring to FIG. 18, the lower source/drain patterns 160A and 160B may be formed.

The lower source/drain patterns 160A and 160B may be formed by an epitaxial growth process of using the lower bridge patterns 111 and 112 as a seed layer. Accordingly, the lower source/drain patterns 160A and 160B connected to the lower active patterns A11 and A12 may be formed.

In some embodiments, a holder pattern 360 may be formed inside the fin pattern 110. The lower source/drain patterns 160A and 160B may be formed on the holder pattern 360. The holder pattern 360 may include a material having an etching selectivity with respect to the base substrate 100 and/or the fin pattern 110. As an example, the base substrate 100 may be a silicon substrate, the fin pattern 110 may be a silicon pattern, and the holder pattern 360 may be a silicon germanium pattern. In some embodiments, unlike the shown example, the holder pattern 360 may be omitted.

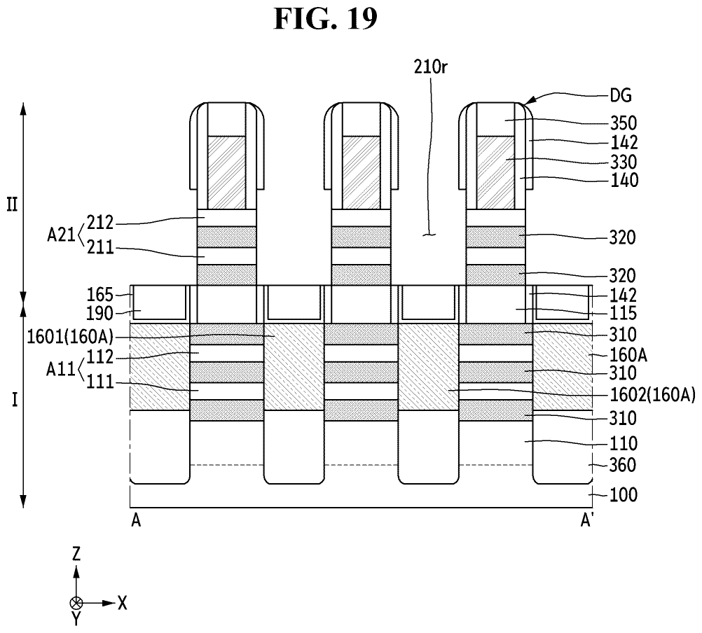

Referring to FIG. 19, a first etch stop layer 165 and a first interlayer insulating film 190 may be formed on the spacer film 142 and the lower source/drain patterns 160A and 160B.

The first etch stop layer 165 and the first interlayer insulating film 190 may cover the lower source/drain patterns 160A and 160B. In some embodiments, the upper face of the first interlayer insulating film 190 may be formed to be lower than the lower faces of the upper active patterns A21 and A22.

After the first etch stop layer 165 and the first interlayer insulating film 190 are formed, the upper bridge patterns 211 and 212 and the second sacrificial patterns 320 may be exposed from the spacer film 142.

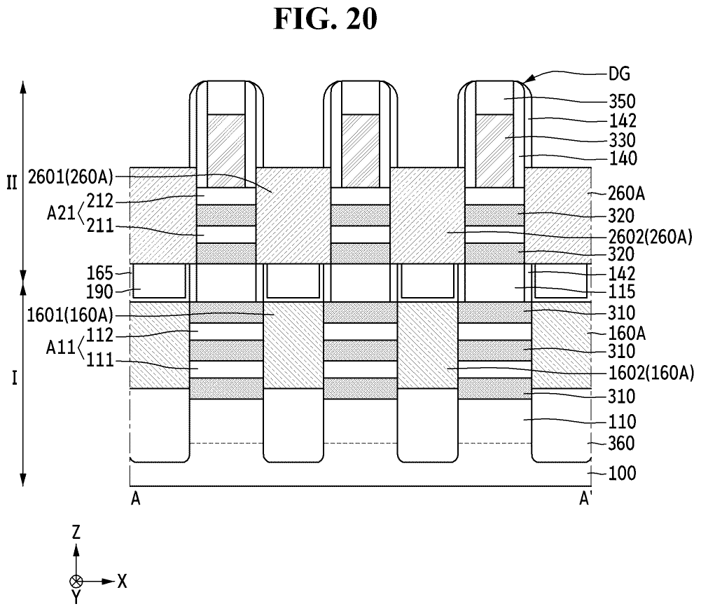

Referring to FIG. 20, the upper source/drain patterns 260A and 260B may be formed.

The upper source/drain patterns 260A and 260B may be formed by an epitaxial growth process of using the upper bridge patterns 211 and 212 as a seed layer. Accordingly, the upper source/drain patterns 260A and 260B connected to the upper active patterns A21 and A22 may be formed.

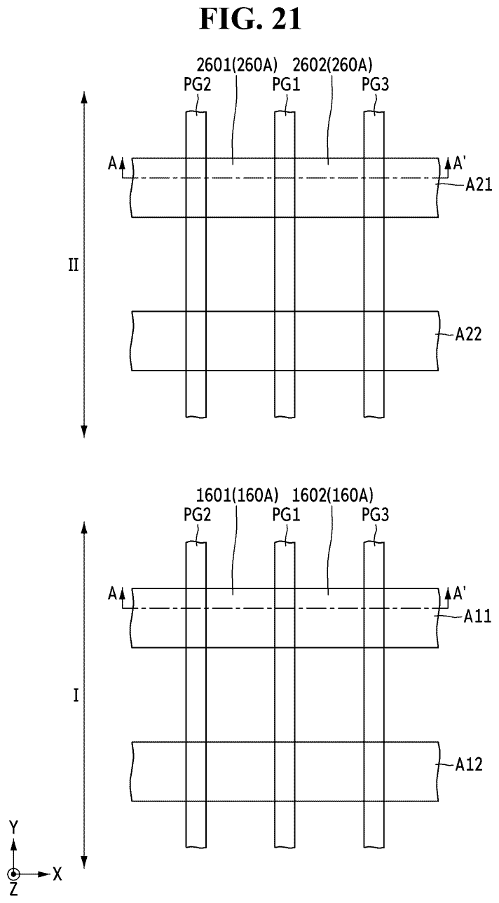

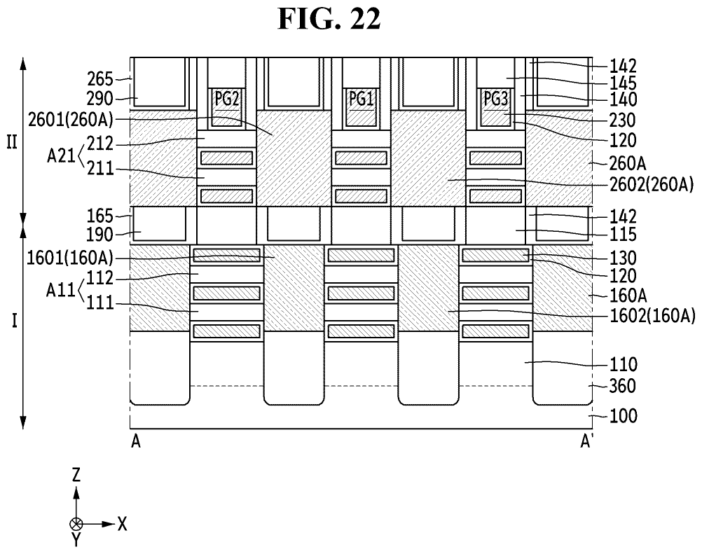

Referring to FIGS. 21 and 22, the preliminary gate structures PG1, PG2 and PG3 are formed.

For example, the second etch stop layer 265 and the second interlayer insulating film 290 may be formed on the upper source/drain patterns 260A and 260B. Next, the gate mask pattern 350, the dummy gate electrode 330, the first sacrificial patterns 310, and the second sacrificial patterns 320 may be sequentially removed. The dummy gate electrode 330, the first sacrificial patterns 310, and the second sacrificial patterns 320 may be selectively removed with respect to the lower bridge patterns 111 and 112 and the upper bridge patterns 211 and 212. Next, a gate dielectric film 120, a first gate electrode 130, and a second gate electrode 230 which replace the region in which the dummy gate electrode 330, the first sacrificial patterns 310, and the second sacrificial patterns 320 are removed may be formed. Next, a gate capping film 145 which covers the upper face of the second gate electrode 230 may be formed. Accordingly, a plurality of preliminary gate structures PG1, PG2 and PG3 including the gate dielectric film 120, the first gate electrode 130, the second gate electrode 230, the gate spacer 140, and the gate capping film 145 may be provided.

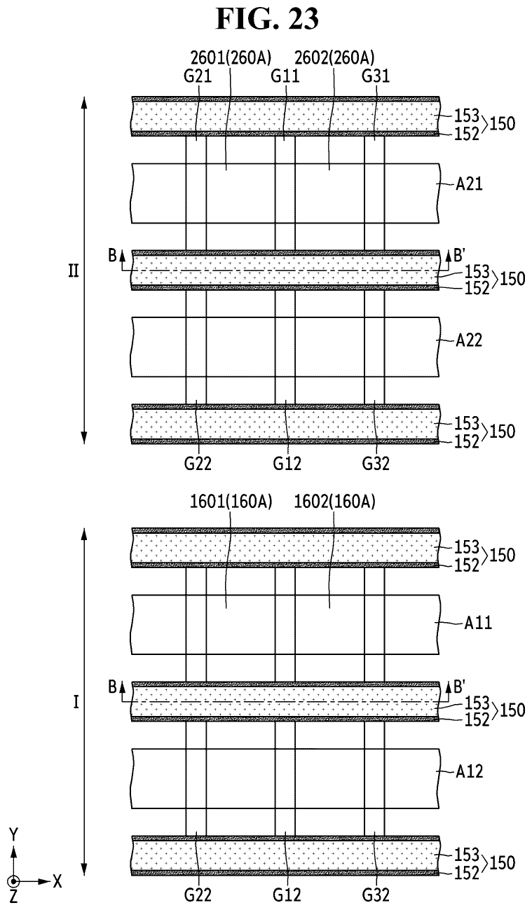

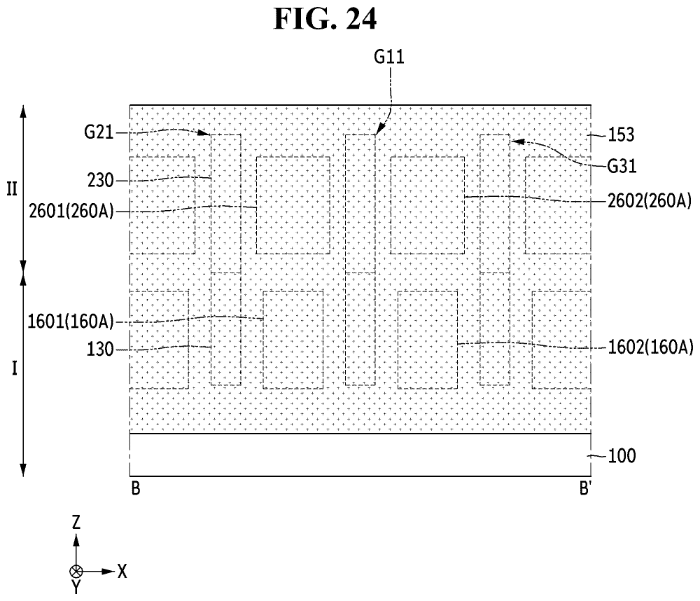

Referring to FIGS. 23 and 24, the cut pattern 150 may be formed.

The cut pattern 150 may be spaced apart from the lower active patterns A11 and A12 and the upper active patterns A21 and A22 in the third direction Y. The cut pattern 150 may extend long in the second direction X, and cut the preliminary gate structures PG1, PG2, and PG3 of FIGS. 21 and 22. Accordingly, the gate structures G11, G12, G21, G22, G31 and G32 may be provided.

In some embodiments, the cut pattern 150 may include a liner insulating film 152 and a sacrificial cut film 153 that are stacked in sequence. The liner insulating film 152 may be interposed between each of the gate structures G11, G12, G21, G22, G31 and G32 and the sacrificial cut film 153.

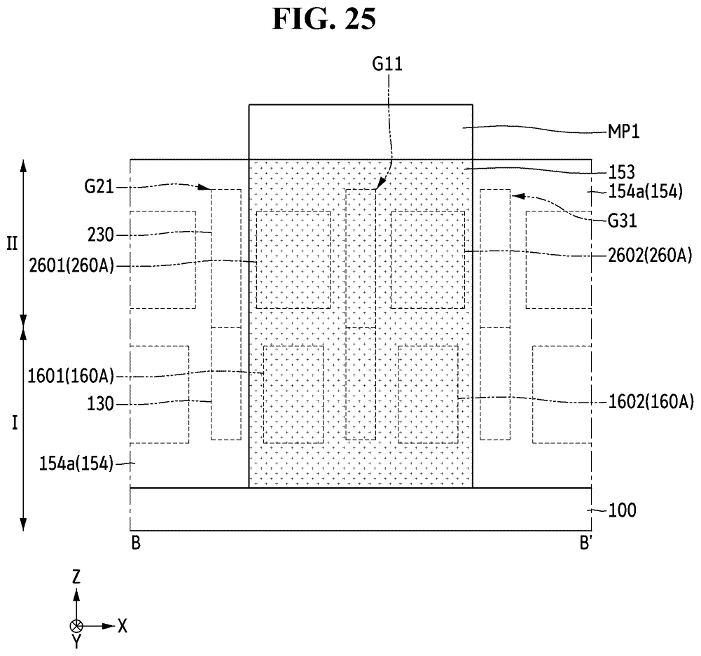

Referring to FIG. 25, the sacrificial cut film 153 may be patterned.

For example, the patterned sacrificial cut film 153 may be formed, using a via mask pattern MP1 formed on the sacrificial cut film 153. In some embodiments, the patterned sacrificial cut film 153 may overlap the first gate structure G11, the first lower epitaxial pattern 1601, the second lower epitaxial pattern 1602, the first upper epitaxial pattern 2601, and the second upper epitaxial pattern 2602 in the third direction Y. Next, a filling insulating film 154 that replaces the region in which the sacrificial cut film 153 is removed may be formed.

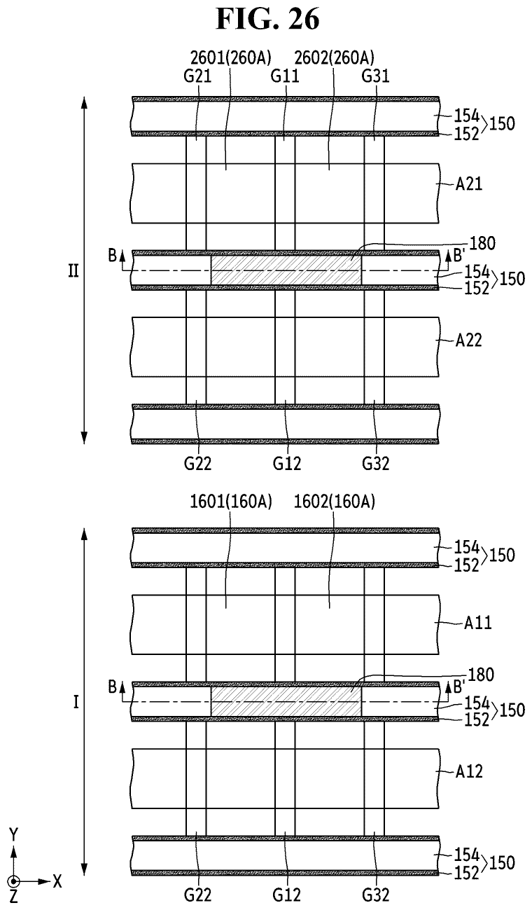

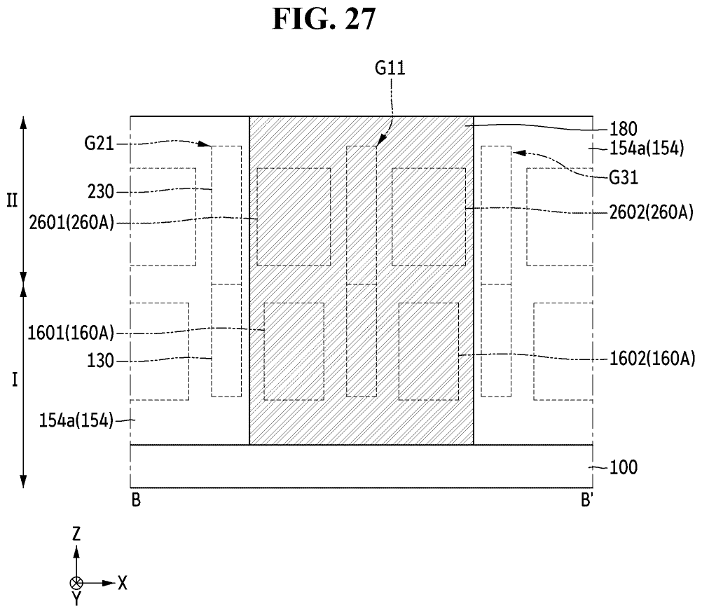

Referring to FIGS. 26 and 27, the via structure 180 may be formed.

For example, the patterned sacrificial cut film 153 may be selectively removed with respect to the filling insulating film 154. Next, the via structure 180 that replaces the region in which the sacrificial cut film 153 is removed may be formed. Accordingly, the via structure 180 that overlaps the first gate structure G11, the first lower epitaxial pattern 1601, the second lower epitaxial pattern 1602, the first upper epitaxial pattern 2601, and the second upper epitaxial pattern 2602 in the third direction Y may be provided.

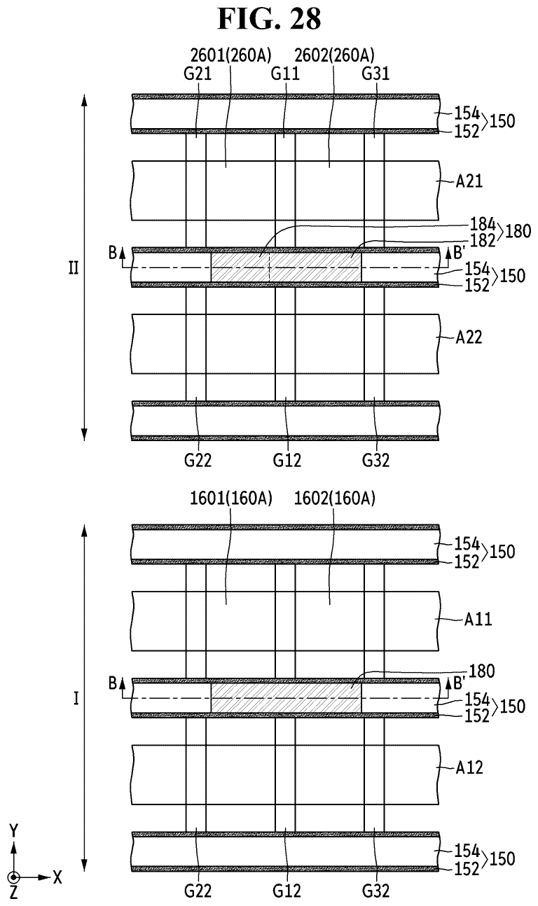

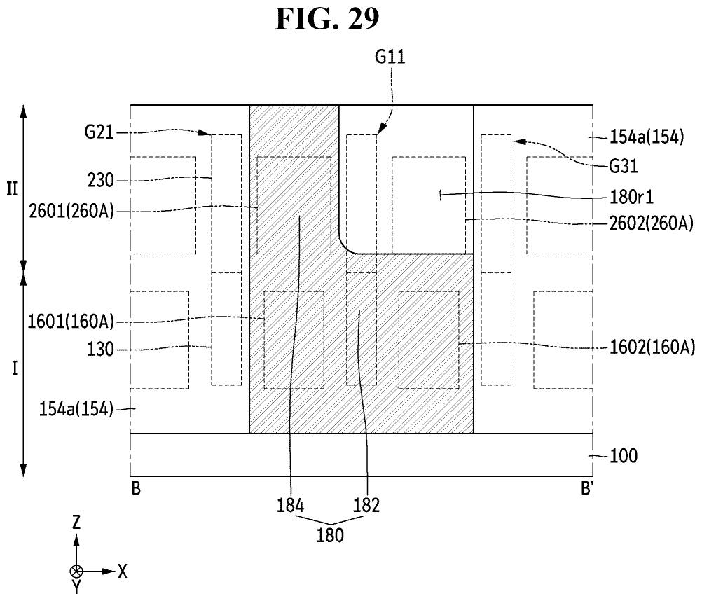

Referring to FIGS. 28 and 29, a recess process may be performed on a part of the via structure 180.

As the recess process is performed, a first via recess 180r1 that extends downward from the upper face of the via structure 180 may be formed. In some embodiments, the first via recess 180r1 may overlap the second upper epitaxial pattern 2602 in the third direction Y. In some embodiments, the first via recess 180r1 may overlap the second gate electrode 230 of the first gate structure G11 in the third direction Y. Accordingly, the via structure 180 including the first pillar part 184 may be provided.

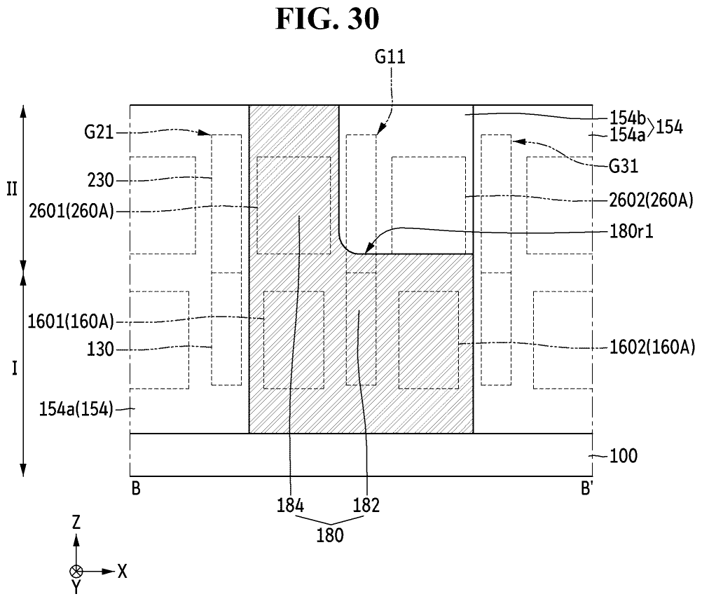

Referring to FIG. 30, a first recess filling film 154b that fills at least a part of the first via recess 180r1 may be formed. Accordingly, the filling insulating film 154 including the first recess filling film 154b may be provided.

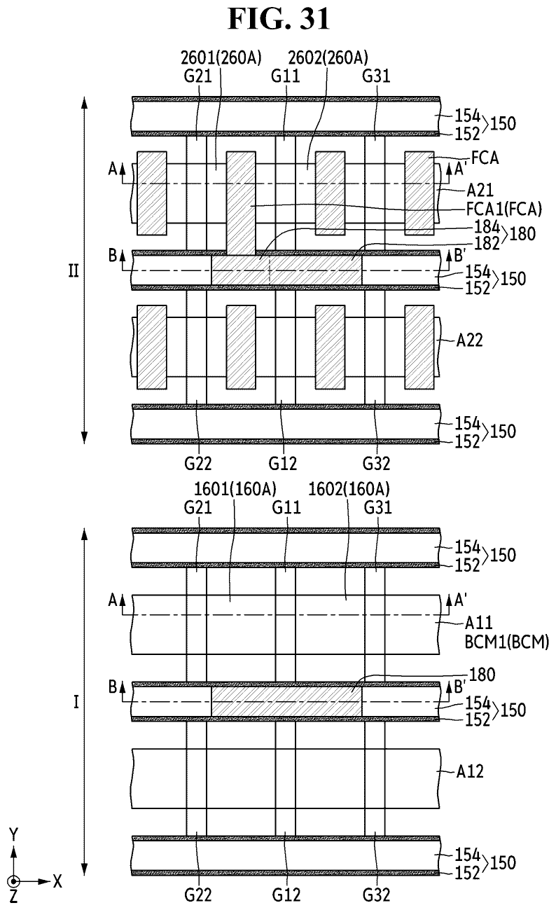

Referring to FIGS. 31 to 33, the first connecting pattern FCA1 and/or the front source/drain contacts FCA may be formed.

The first connecting pattern FCA1 may extend in the third direction Y and (electrically) connect the first upper epitaxial pattern 2601 and the first pillar part 184.

The front source/drain contacts FCA penetrate (extend in) the second interlayer insulating film 290 and the second etch stop layer 265, and may be (electrically) connected to the upper source/drain patterns 260A and 260B. In some embodiments, the front source/drain contact FCA may include a first connecting pattern FCA1.

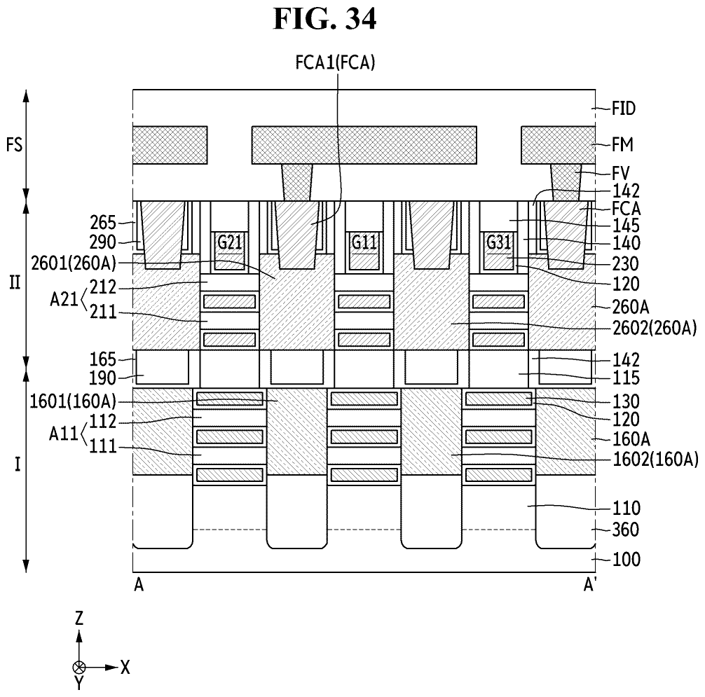

Referring to FIG. 34, a front wiring structure FS may be formed.

The front wiring structure FS may be electrically connected to the upper source/drain patterns 260A and 260B and/or the second gate electrode 230.

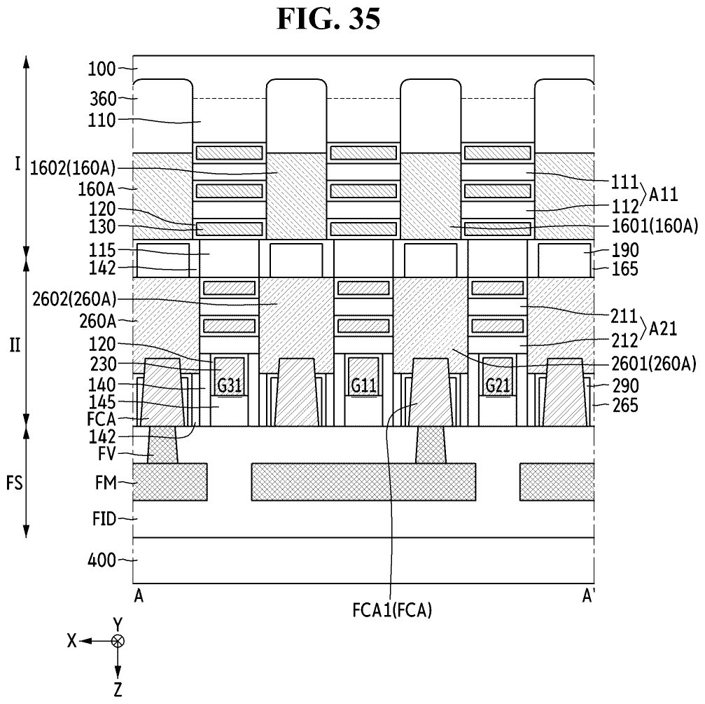

Referring to FIG. 35, the front wiring structure FS may be attached onto a carrier substrate 400.

For example, the carrier substrate 400 may be attached onto the result of FIG. 34. After the carrier substrate 400 is attached, the result of FIG. 34 may be inverted.

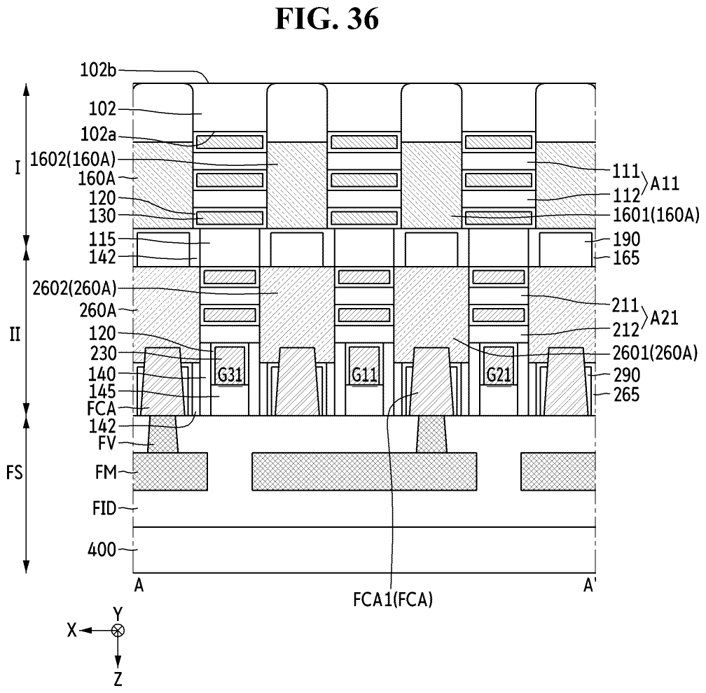

Referring to FIG. 36, a substrate 102 may be formed.

For example, the base substrate 100 and the fin pattern 110 may be removed. Next, the substrate 102 may be formed in the region in which the base substrate 100 and the fin pattern 110 are removed. In some embodiments, the base substrate 100 and the fin pattern 110 may be selectively removed with respect to the holder pattern 360.

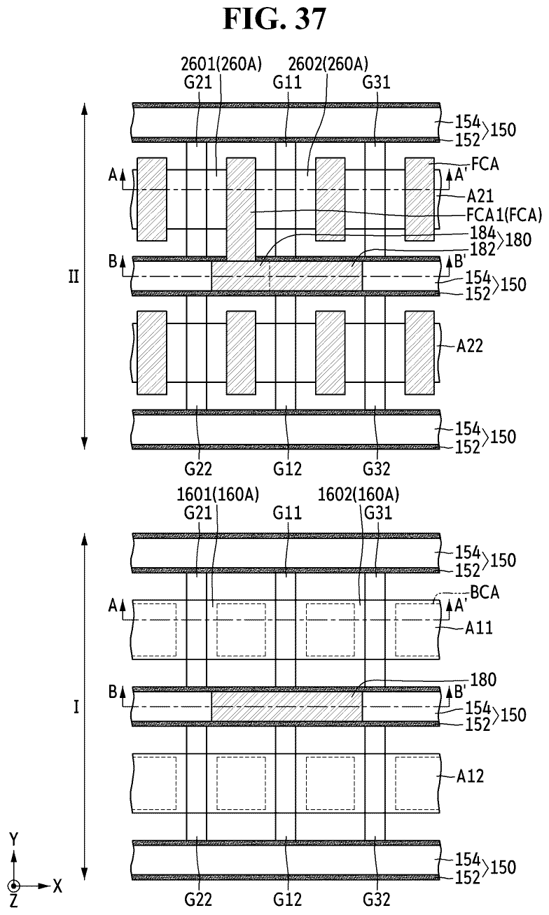

Referring to FIGS. 37 to 39, the back source/drain contacts BCA are formed.

The back source/drain contacts BCA penetrate (extend in) the substrate 102, and may be (electrically) connected to the lower source/drain patterns 160A and 160B.

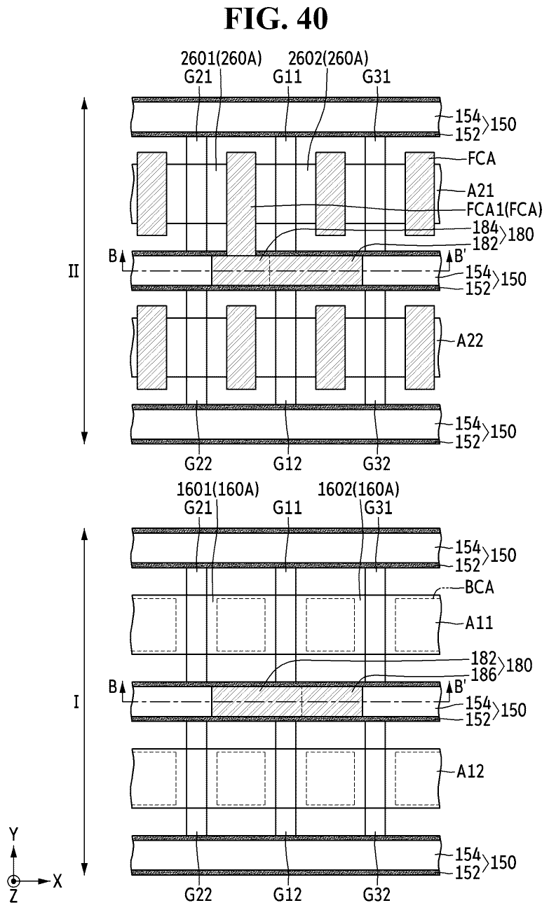

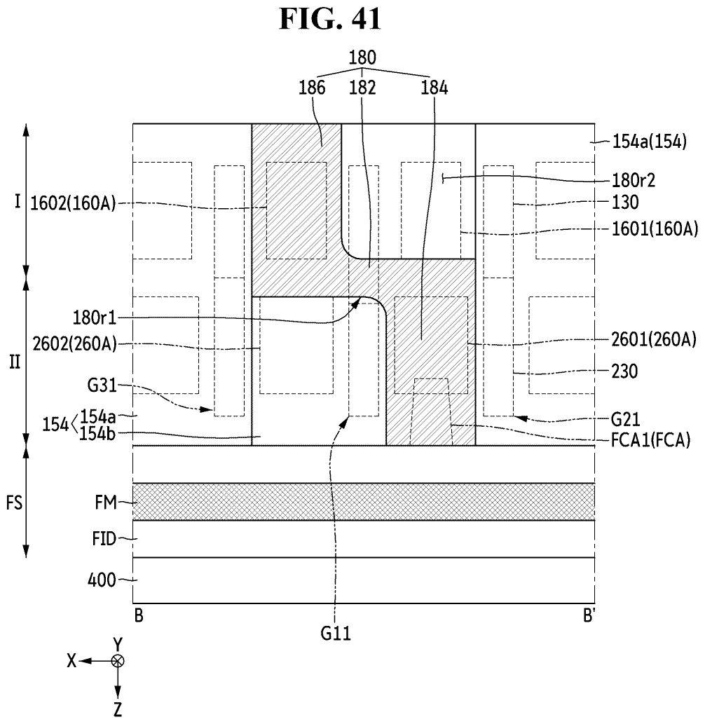

Referring to FIGS. 40 and 41, a recess process may be performed on a part of the via structure 180.

As the recess process is performed, the second via recess 180r2 extending downward from the upper face of the via structure 180 may be formed. In some embodiments, the second via recess 180r2 may overlap the first lower epitaxial pattern 1601 in the third direction Y. In some embodiments, the second via recess 180r2 may overlap the first gate electrode 130 of the first gate structure G11 in the third direction Y. Accordingly, the via structure 180 including the second pillar part 186 may be provided.

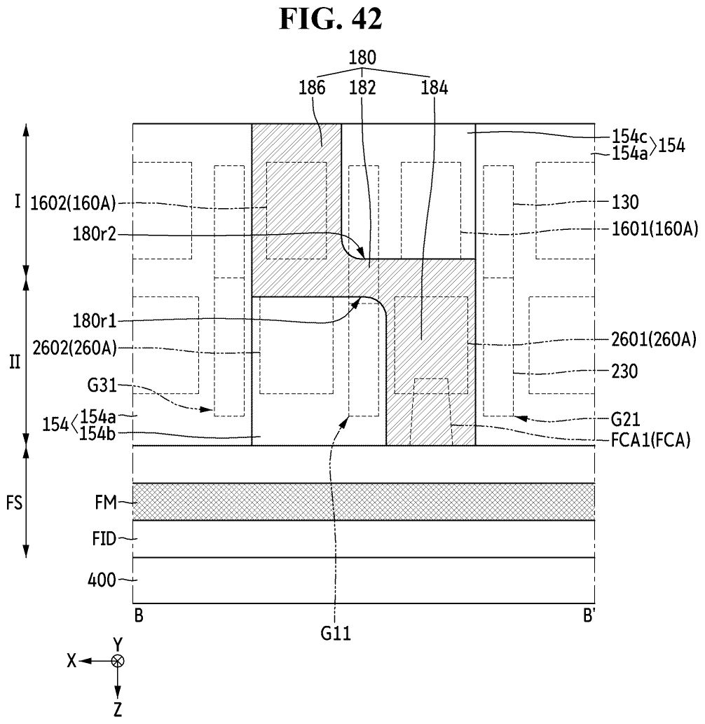

Referring to FIG. 42, a second recess filling film 154c that fills at least a part of the second via recess 180r2 may be formed. Accordingly, the filling insulating film 154 including the second recess filling film 154c may be provided.

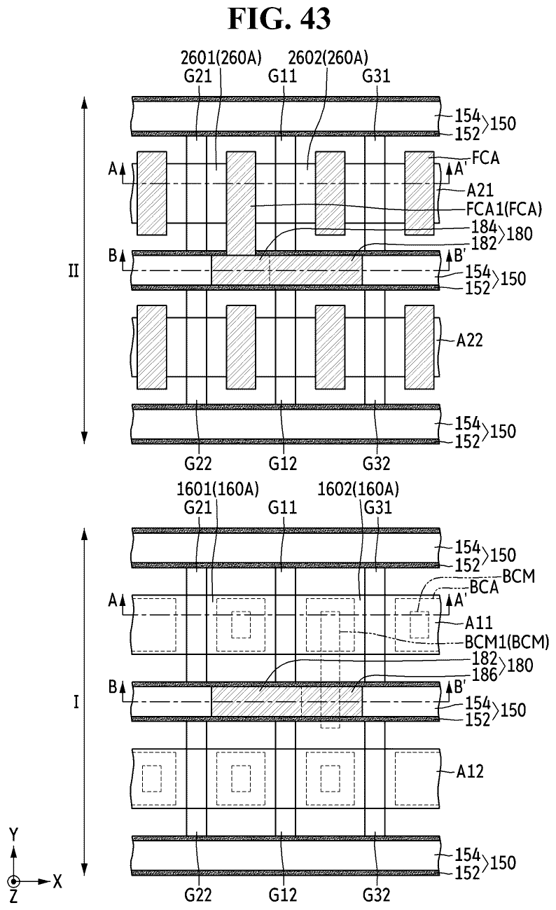

Referring to FIGS. 43 to 45, the second connecting pattern BCM1 and/or the back connecting contacts BCM may be formed.

The second connecting pattern BCM1 may extend in the third direction Y, and (electrically) connect the second lower epitaxial pattern 1602 and the second pillar part 186.

The back connecting contacts BCM penetrate (extend in) the third interlayer insulating film 109, and may be (electrically) connected to the back source/drain contacts BCA. In some embodiments, the back connecting contacts BCM may include a second connecting pattern BCM1.

Next, referring to FIGS. 1 to 3, the back wiring structure BS may be formed.

The back wiring structure BS may be electrically connected to the lower source/drain patterns 160A and 160B and/or the first gate electrode 130. Accordingly, the semiconductor device explained above using FIGS. 1 to 6 may be provided.

While the present inventive concept has been particularly shown and described with reference to exemplary embodiments thereof, it will be understood by those of ordinary skill in the art that various changes in form and details may be made therein without departing from the scope of the present inventive concept as defined by the following claims. It is therefore desired that the present embodiments be considered in all respects as illustrative and not restrictive, reference being made to the appended claims rather than the foregoing description to indicate the scope of the invention.

What is claimed is:

1. A semiconductor device comprising:
a substrate;
an upper active pattern that extends in a first direction on the substrate;
a lower active pattern between the upper active pattern and an upper face of the substrate in a second direction that intersects the first direction and the upper face of the substrate, wherein the lower active pattern extends in the first direction;
a gate structure that extends in a third direction that intersects the first direction and the second direction, on the lower active pattern and the upper active pattern;
a first lower epitaxial pattern on a first side of the gate structure, wherein the first lower epitaxial pattern is connected to the lower active pattern;
a first upper epitaxial pattern on a second side of the gate structure, wherein the first upper epitaxial pattern is connected to the upper active pattern;
a cut pattern that is spaced apart from the lower active pattern and the upper active pattern in the third direction, is adjacent the gate structure, and extends in the first direction; and
a via structure that is connected to the first lower epitaxial pattern and the first upper epitaxial pattern, in the cut pattern,
wherein the via structure includes a first pillar part that overlaps the first upper epitaxial pattern in the third direction, a second pillar part that overlaps the first lower epitaxial pattern in the third direction, and a connecting part that extends in the first direction and connects the first pillar part and the second pillar part.

2. The semiconductor device of claim 1,
wherein the first pillar part, the second pillar part, and the connecting part are integrally connected to each other.

3. The semiconductor device of claim 1, further comprising:
an intermediate insulating pattern between the lower active pattern and the upper active pattern,
wherein the connecting part overlaps the gate structure and the intermediate insulating pattern in the third direction.

4. The semiconductor device of claim 1, further comprising:
a second upper epitaxial pattern that is connected to the upper active pattern on the first side of the gate structure,
wherein the first pillar part is free of overlap with the second upper epitaxial pattern in the third direction.

5. The semiconductor device of claim 1, further comprising:
a second lower epitaxial pattern which is connected to the lower active pattern on the second side of the gate structure,
wherein the second pillar part is free of overlap with the second lower epitaxial pattern in the third direction.

6. The semiconductor device of claim 1, further comprising:
a first connecting pattern on an upper face of the first upper epitaxial pattern,
wherein the first connecting pattern extends in the third direction, and connects the first upper epitaxial pattern and the first pillar part.

7. The semiconductor device of claim 1, further comprising:
a second connecting pattern on a lower face of the first lower epitaxial pattern,
wherein the second connecting pattern extends in the third direction, and connects the first lower epitaxial pattern and the second pillar part.

8. The semiconductor device of claim 1,
wherein the first lower epitaxial pattern includes an impurity of a first conductivity type, and
wherein the first upper epitaxial pattern includes an impurity of a second conductivity type that is different from the first conductivity type.

9. The semiconductor device of claim 1,
wherein the cut pattern includes a liner insulating film and a filling insulating film that are sequentially stacked on a side face of the gate structure, and
wherein the liner insulating film is between the via structure and the gate structure.

10. A semiconductor device comprising:
a substrate;
an upper active pattern that extends in a first direction on the substrate;
a lower active pattern between the upper active pattern and an upper face of the substrate in a second direction that intersects the first direction and the upper face of the substrate, wherein the lower active pattern extends in the first direction;
a gate structure that extends in a third direction that intersects the first direction and the second direction, on the lower active pattern and the upper active pattern;
a first lower epitaxial pattern on a first side of the gate structure, wherein the first lower epitaxial pattern is connected to the lower active pattern;
a second lower epitaxial pattern on a second side of the gate structure, wherein the second lower epitaxial pattern is connected to the lower active pattern;
a first upper epitaxial pattern on the first side of the gate structure, wherein the first upper epitaxial pattern is connected to the upper active pattern;
a second upper epitaxial pattern on the second side of the gate structure, wherein the second upper epitaxial pattern is connected to the upper active pattern;
a cut pattern that is spaced apart from the lower active pattern and the upper active pattern in the third direction, is adjacent the gate structure, and extends in the first direction; and
a via structure that is connected to the second lower epitaxial pattern and the first upper epitaxial pattern, in the cut pattern,
wherein the via structure includes a first via recess that extends from an upper face of the via structure and overlaps the second upper epitaxial pattern in the third direction, and a second via recess that extends from a lower face of the via structure and overlaps the first lower epitaxial pattern in the third direction.

11. The semiconductor device of claim 10,
wherein the first via recess includes a curved face that connects a lower face of the first via recess and a side face of the first via recess.

12. The semiconductor device of claim 10,
wherein the second via recess includes a curved face that connects an upper face of the second via recess and a side face of the second via recess.

13. The semiconductor device of claim 10,
wherein a first distance of a lower face of the first via recess to the upper face of the substrate is equal to or less than a second distance of a lower face of the second upper epitaxial pattern to the upper face of the substrate.

14. The semiconductor device of claim 10,
wherein a first distance of an upper face of the second via recess from the upper face of the substrate is equal to or greater than a second distance of an upper face of the first lower epitaxial pattern from the upper face of the substrate.

15. The semiconductor device of claim 10,
wherein the cut pattern includes a liner insulating film and a filling insulating film that are sequentially stacked on a side face of the gate structure,
wherein the liner insulating film is between the via structure and the gate structure, and
wherein the filling insulating film is in the first via recess and the second via recess.

16. A semiconductor device comprising:
a substrate that includes a first face and a second face that is opposite to the first face in a first direction;
a lower active pattern and an upper active pattern that are sequentially stacked in the first direction, and each extend in a second direction that intersects the first direction;
an intermediate insulating pattern between the lower active pattern and the upper active pattern;
a gate structure that extends in a third direction that intersects the first direction and the second direction, wherein each of the lower active pattern and the upper active pattern penetrates through the gate structure;
a first lower epitaxial pattern on a first side of the gate structure, wherein the first lower epitaxial pattern is connected to the lower active pattern;
a second lower epitaxial pattern on a second side of the gate structure, wherein the second lower epitaxial pattern is connected to the lower active pattern;
a first upper epitaxial pattern on the first side of the gate structure, wherein the first upper epitaxial pattern is connected to the upper active pattern;
a second upper epitaxial pattern on the second side of the gate structure, wherein the second upper epitaxial pattern is connected to the upper active pattern;
a cut pattern that is spaced apart from the lower active pattern and the upper active pattern in the third direction, is adjacent the gate structure, and extends in the second direction;
a via structure in the cut pattern, wherein the via structure includes a connecting part that overlaps the intermediate insulating pattern and the gate structure in the third direction, a first pillar part that overlaps the first upper epitaxial pattern and is free of overlap with the second upper epitaxial pattern in the third direction, and a second pillar part that overlaps the second lower epitaxial pattern and is free of overlap with the first lower epitaxial pattern in the third direction;
a first connecting pattern that extends in the third direction on an upper face of the first upper epitaxial pattern, and connects the first upper epitaxial pattern and the first pillar part; and
a second connecting pattern that extends in the third direction on a lower face of the second lower epitaxial pattern, and connects the second lower epitaxial pattern and the second pillar part.

17. The semiconductor device of claim 16,
wherein the first connecting pattern is in contact with a side face of the first pillar part.

18. The semiconductor device of claim 16,
wherein the second connecting pattern is in contact with a lower face of the second pillar part.

19. The semiconductor device of claim 16, further comprising:
a front wiring structure that is electrically connected to the second upper epitaxial pattern, on the first face of the substrate.

20. The semiconductor device of claim 16, further comprising:
a back wiring structure that is electrically connected to the first lower epitaxial pattern, on the second face of the substrate.
